(19) United States
(12) Patent Application Publication
(10) Pub. No.: US 2023/0207581 A1
(43) Pub. Date: Jun. 29, 2023

(54) OPTICAL SENSING DEVICE

(71) Applicant: Amengine Corporation, Zhubei City (TW)

(72) Inventors: Jian-Yu SHEN, Hsinchu (TW); Chia-Liang HSU, Zhubei City (TW)

(21) Appl. No.: 18/089,734

(22) Filed: Dec. 28, 2022

Related U.S. Application Data
(60) Provisional application No. 63/294,524, filed on Dec. 29, 2021.

(30) Foreign Application Priority Data
Dec. 27, 2022 (TW) 111150227

(51) Int. Cl. H01L 27/144; H01L 31/0236; H01L 31/024; H01L 31/0232

(52) U.S. Cl. CPC H01L 27/1446; H01L 31/02363; H01L 31/024; H01L 31/02327

(57) ABSTRACT

An optical sensing device is provided. The optical sensing device includes a substrate, a housing, a light receiver, and an optical structure. The housing is disposed on an upper surface of the substrate, and the housing and the substrate collectively define a cavity. The light receiver is disposed in the cavity, and the housing surrounds the light receiver. The optical structure is disposed on an upper surface of the light receiver, and the optical structure includes a plurality of concave portions and a plurality of convex portions. The concave portions and the convex portions are alternately arranged to form an array, and a light transmittance of the concave portions is greater than a light transmittance of the convex portions.

### CROSS-REFERENCES TO RELATED APPLICATIONS

This Application claims priority of Taiwan Patent Application No.111150227, filed on Dec. 27, 2022, which claims priority of U.S. provisional application No. 63/294,524, filed on Dec. 29, 2021, the entirety of which is incorporated by reference herein.

### BACKGROUND

### Technical Field

The instant disclosure relates to an optical sensing device, in particular, to a structure of an optical sensing device.

### Related Art

Due to the vigorous development of industrial technology, human life has become more comfortable and longer, but people also have to face diseases caused by the change of the life styles and aging. These diseases include Alzheimer's disease, arteriosclerosis, tumors, chronic liver disease due to cirrhosis, chronic obstructive pulmonary disease, diabetes, heart disease, nephritis due to chronic renal failure, osteoporosis, stroke, obesity, and so on. Most of the diseases are chronic diseases. Therefore, if there is an approach to monitor the physiological data in a more precise, convenient, comfortable, and long-term manner, the doctor can give instant or earlier medical advices for the patients.

At present, common health detection devices in the market include watches, bracelets, earphones, mobile phones, portable detection devices, and other electronic products. Although a variety of physiological data measurement technologies have been applied to various electronic products, the accuracy of these measurement technologies is still insufficient. As a result, these measurement technologies fail to provide reliable measurement for doctors as diagnostic reference. Therefore, considering the development trend of medical devices in the future, how to effectively improve the detection accuracy, such as, increasing the signal-to-noise ratio of detection devices, is a problem to be solved.

### SUMMARY

In one embodiment, the optical sensing device includes a substrate, a housing, a light receiver, and an optical structure. The housing is disposed on an upper surface of the substrate, and the housing and the substrate collectively define a cavity. The light receiver is disposed in the cavity and is surrounded by the housing. The optical structure is disposed on an upper surface of the light receiver. The optical structure includes a plurality of concave portions and a plurality of convex portions, the concave portions and the convex portions are alternately arranged to form an array, and a light transmittance of the concave portions is greater than a light transmittance of the convex portions.

Another embodiment of the instant disclosure provides an optical sensing device. The sensing device includes a substrate, a housing, a light receiver, a light-transmittable material, and an optical structure. The housing is disposed on an upper surface of the substrate, and the housing and the substrate collectively define a cavity. The light receiver is disposed in the cavity, and the housing surrounds the light receiver. The light-transmittable material is filled in the cavity, and an upper surface of the transparent filing layer and an upper surface of the housing are coplanar. The optical structure is disposed on the upper surface of the light-transmittable material, the optical structure includes a plurality of concave portions and a plurality of convex portions, the concave portions and the convex portions are alternately arranged to form an array, and a light transmittance of the concave portions is greater than a light transmittance of the convex portions.

### BRIEF DESCRIPTION OF THE DRAWINGS

The disclosure will become more fully understood from the detailed description given herein below for illustration only, and thus not limitative of the disclosure, wherein:

FIG. 1 is a schematic cross-sectional view of an optical sensing module in accordance with an embodiment of the instant disclosure;

FIG. 2A and FIG. 2B are schematic views of optical structures in accordance with embodiments of the instant disclosure;

FIGS. 3A to 3E are schematic views of optical structures in accordance with embodiments of the instant disclosure;

FIGS. 4A to 4E are schematic views and photographs of optical structures in accordance with embodiments of the instant disclosure;

FIGS. 4F is a diagram showing the relationship between the incident angle of the optical structure and the light transmittance;

FIGS. 4G to 4I are schematic views and photographs of optical structure in accordance with embodiments of the instant disclosure;

FIG. 4J is a diagram showing the relationship between the incident angle of the optical structure and the light transmittance;

FIGS. 5A to 5C are schematic views showing the manufacturing processes of an optical sensing device in accordance with one embodiment of the instant disclosure;

FIGS. 6A to 6D are schematic views showing the manufacturing processes of an optical sensing device in accordance with one embodiment of the instant disclosure;

FIGS. 7A to 7E are schematic views showing the manufacturing processes of an optical sensing device in accordance with one embodiment of the instant disclosure;

FIGS. 8A to 8D are schematic cross-sectional views of optical sensing devices in accordance with embodiments of the instant disclosure;

FIGS. 9A to 9C are schematic views showing the manufacturing processes of an optical sensing device in accordance with one embodiment of the instant disclosure;

FIG. 10A is a schematic view showing an optical material layer in accordance with one embodiment of the instant disclosure;

FIG. 10B illustrates the light path of the light passing through the optical material layer in accordance with one embodiment of the instant disclosure;

FIGS. 10C to 10F are diagrams showing the relationship between the wavelength of the light passing through the optical structure and the light transmittance;

FIG. 11A and FIG. 11B are schematic top views of optical structures in accordance with one embodiment of the instant disclosure;

FIGS. 12A to 12D are schematic cross-sectional views of optical sensing module in accordance with one embodiment of the instant disclosure;

FIG. 12E is a schematic view of an optical structure in accordance with one embodiment of the instant disclosure; and

FIGS. 13A to 13F are schematic views showing the application scenarios of optical sensing devices/modules in accordance with embodiments of the instant disclosure.

### DETAILED DESCRIPTION

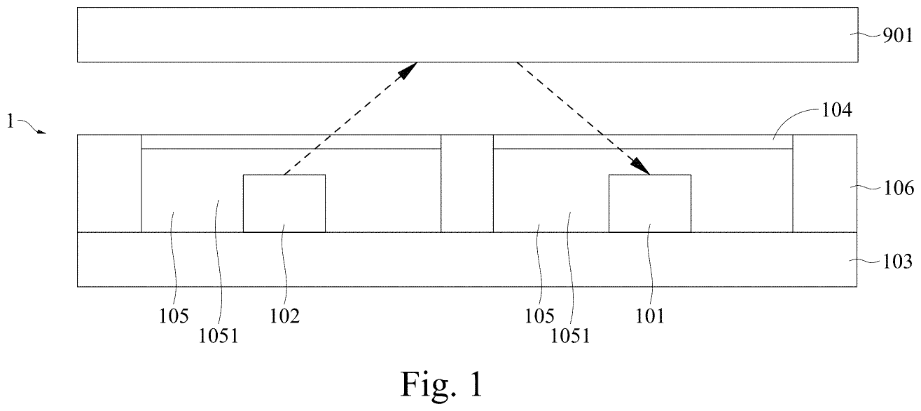

FIG. 1 is a schematic cross-sectional view of an optical sensing device in accordance with an embodiment of the instant disclosure. In one embodiment, the optical sensing device 1 can be attached to a surface of the skin tissue 901 of an organism so as to be adapted to biometric recognition or is adapted to sense a physiological signal of the organism with photoplethysmography (PPG). The physiological signal can be blood oxygen concentration, muscle oxygen concentration, brain oxygen concentration, heartrate, blood pressure, lactic acid concentration, atrial fibrillation, moisture content, blood sugar concentration, body temperature, and blood flow rate.

As shown in FIG. 1, the optical sensing device 1 includes a substrate 103, a housing 106, a light receiver 101, and a light emitter 102. The housing 106 is disposed on an upper surface of the substrate 103, the housing 106 and the substrate 103 define two separated cavities 105. The light receiver 101 and the light emitter 102 are respectively disposed in the two independent cavities 105. The light receiver 101 and the light emitter 102 are respectively surrounded by the housing 106. The two cavities 105 are respectively covered by two covers 104. The two covers 104 can protect the light receiver 101 and the light emitter 102 to prevent the light receiver 101 and the light emitter 102 from being directly affected by the external force or prevent moisture from leaking into the optical sensing device 1. The covers 104 can be permanently or temporarily fixed on the cavities 105. In the case that the covers 104 are temporarily fixed on the cavities 105, when the covers 104 are damaged, the covers 104 can be replaced. In one embodiment, the cavities 105 are filled with a light-transmittable material 1051. In another embodiment, the cavities 105 can be kept vacuumed or filled with an inert gas, such as nitrogen.

In one embodiment, the substrate 103 can be a flexible circuit board. The substrate 103 includes an insulation material and a circuit structure. The insulation material can be polyimide, polyester film (PET), bismaleimide triazine (BT), or Ajinomoto build-up film (ABF). The circuit structure of the substrate 103 is adapted to be electrically connected to the light receiver 101, the light emitter 102, and/or other electronic elements.

The housing 106 can be an opaque structure to prevent ambient stray lights from entering the cavities 105 through lateral sides of the housing 106. The material of the housing 106 can be germanium fabrics, polyimide (PI), polyester film, silastic, mica sheet, thermoplastic polyurethane (TPU), polytetrafluoroethylene (PTFE), benzocyclobutene (BCB), perfluorocyclobutane (PFCB), epoxy resin, Su8 photoresist, spin-on glass (SOG), or silicone.

The light receiver 101 and the light emitter 102 are disposed on the upper surface of the substrate 103. The light receiver 101 can be a photodiode, a photoresistor, or a visible or invisible light sensor. The light emitter 102 can be a laser diode (LD), an organic light emitting diode (OLED), an LED, or other light sources. In one embodiment, the light emitter 102 is adapted to emit a light (for example, a green light having a wavelength between 500 nm and 580 nm, a red light having a wavelength between 610 nm and 700 nm, or an infrared light having a wavelength between 700 nm and 2000 nm) toward the skin tissue 901 of the organism so as to implement a photoplethysmography measurement. The light can pass through the subcutaneous tissues, the muscle tissues, the somatic cells, the arteries, the veins, or the like. When the light passes through the skin and enters an organism, for example the human body, the light is scattered or reflected by the human cells or the bloods and emitted out of the skin so as to be received by the light receiver 101. The scattered or reflected lights are recorded and analyzed, so that physiological information such as heartbeats, blood oxygen levels, blood sugar levels, and blood pressures can be retrieved from the light signals. To obtain more accurate physiological information, the signal-to-noise ratio of the scattered or reflected light signals have to be increased. The method of increasing the signal-to-noise ratio includes increasing the luminous intensity of the light emitter 102 and retarding ambient stray lights.

The light emitted by the light emitter 102 and the light scattered or reflected by the organism are allowed to pass through the light-transmittable material 1051 and the covers 104. The material of the light-transmittable material 1051 or the covers 104 can be silicone, epoxy resin, polyimide (PI), benzocyclobutene (BCB), perfluorocyclobutane (PFCB), Sub photoresist, acrylic resin, poly(methyl methacrylate) (PMMA), polyethylene terephthalate (PET), polycarbonate (PC), polyetherimide (PEI), fluorocarbon polymer, aluminum oxide (Al₂O₃), siloxane polymer (SINR), or spin-on glass (SOG).

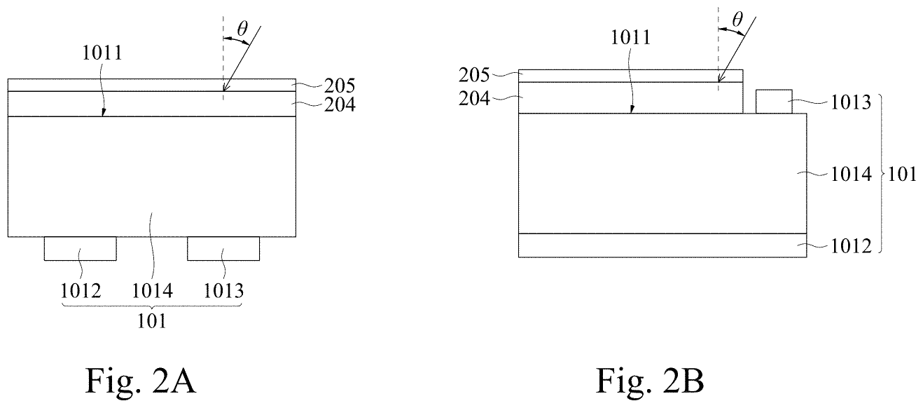

As shown in FIG. 1, the light receiver 101 and the light emitter 102 are respectively disposed in the two cavities 105, and the housing 106 blocks a part of the ambient stray lights. As shown in FIG. 2A and FIG. 2B, in one embodiment, in order to improve the effect of the optical sensing device 1 on suppressing ambient stray light, an optical structure 204 is disposed on the light receiving surface 1011 of the light receiver 101 to increase the light receiving efficiency.

FIG. 2A is a schematic view of a light receiver 101 in a flip-chip type in accordance with an embodiment of the instant disclosure. In one embodiment, the flip-chip type light receiver 101 includes a semiconductor stack 1014 having a light receiving surface 1011, a first electrode pad 1012, and a second electrode pad 1013. The first electrode pad 1012 and the second electrode pad 1013 are located at the same side of the semiconductor stack 1014, the light receiving surface 1011 is located on a side of the semiconductor stack 1014 opposite to the first electrode pad 1012 and the second electrode pad 1013, and the optical structure 204 is disposed on the light receiving surface 1011. As shown in FIG. 2, in one embodiment, a package layer 205 is optionally disposed on the optical structure 204 and adapted to protect the optical structure 204 so as to prevent the optical structure 204 from being damaged by an external force. In another embodiment, the package layer 205 can function as a lens for adjusting the incident angle θ of the incident light.

FIG. 2B is a schematic view of a light receiver 101 in a vertical type in accordance with an embodiment of the instant disclosure. In one embodiment, the vertical-type light receiver 101 includes a semiconductor stack 1014 having a light receiving surface 1011, a bottom surface opposite to the light receiving surface 1011, a first electrode pad 1012, and a second electrode pad 1013. The first electrode pad 1012 and the second electrode pad 1013 are respectively disposed on two opposite sides of the semiconductor stack 1014. The first electrode layer 1012 is disposed below a bottom surface of the semiconductor stack 1014, the second electrode layer 1013 is disposed on a top surface of the light receiving surface 1011, and the optical structure 204 is disposed on a portion of the surface of the light receiving surface 1011 not covered by the second electrode pad 1013.

The optical structure 204 can be formed by a light absorbing material or a light reflecting material. The light absorbing material can include a light absorbing substance, or a mixture of a light absorbing substance and a matrix, wherein the light absorbing substance can be graphite or carbon black, and the matrix can be polyimide, silicone-based resin, or epoxy resin. The light reflecting material can include a light reflecting substance, or a mixture of a light reflecting substance and a matrix, wherein the matrix can be polyimide, silicone-based resin, or epoxy resin, and the light reflecting substance can be metals or oxides. The oxides can be titanium dioxide, silicon dioxide, aluminum oxide, potassium metatitanate (K₂TiO₃), zirconium dioxide (ZrO₂), zinc sulfide (ZnS), zinc oxide (ZnO), magnesium oxide (MgO), or indium tin oxide (ITO). The metals can be a metal with a reflectivity higher than 50%, for example, gold, silver, platinum or the like. In other embodiment, the optical structure 204 can directly contact the human body, thus the material of the optical structure 204 can be a biocompatible material (for example, a medical-level material compatible with the ISO 10993 standard) which can be medical-level elastomer or silicone rubber so as to prevent side effects such as skin allergy, erosion, or irritation.

In one embodiment, the optical structure 204 has a micro-scale or nano-scale patterned structure. In another embodiment, from a macroscale perspective, the optical structure 204 is a film structure having a flat surface without patterned structure. As shown in FIG. 2A and FIG. 2B, in one embodiment, the optical structure 204 is merely allowed to guide the incident light having an incident angle θ less than a certain angle to enter the light receiver 101. In other words, the incident light having the incident angle θ greater than a certain angle is absorbed and/or reflected by the optical structure 204 and does not pass through the optical structure 204. In one embodiment, the certain angle is 30, 35, 40, 45, 50, 55 or 60 degrees. In general, the ambient stray light usually has a greater incident angle θ. Therefore, the light receiver 101 in which the optical structure 204 is disposed on the light receiving surface 1011 can eliminate the ambient stray light noises, thereby increasing the signal-to-noise ratio of the optical sensing device 1.

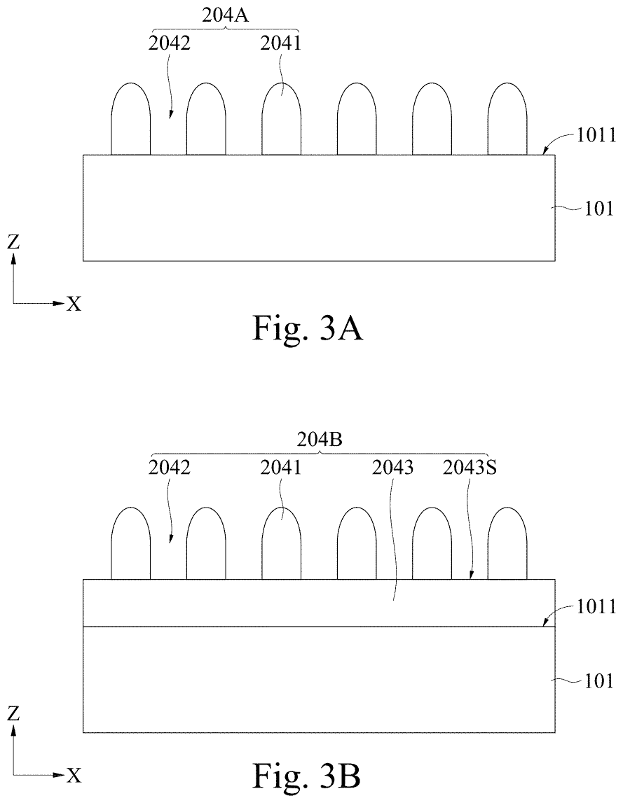

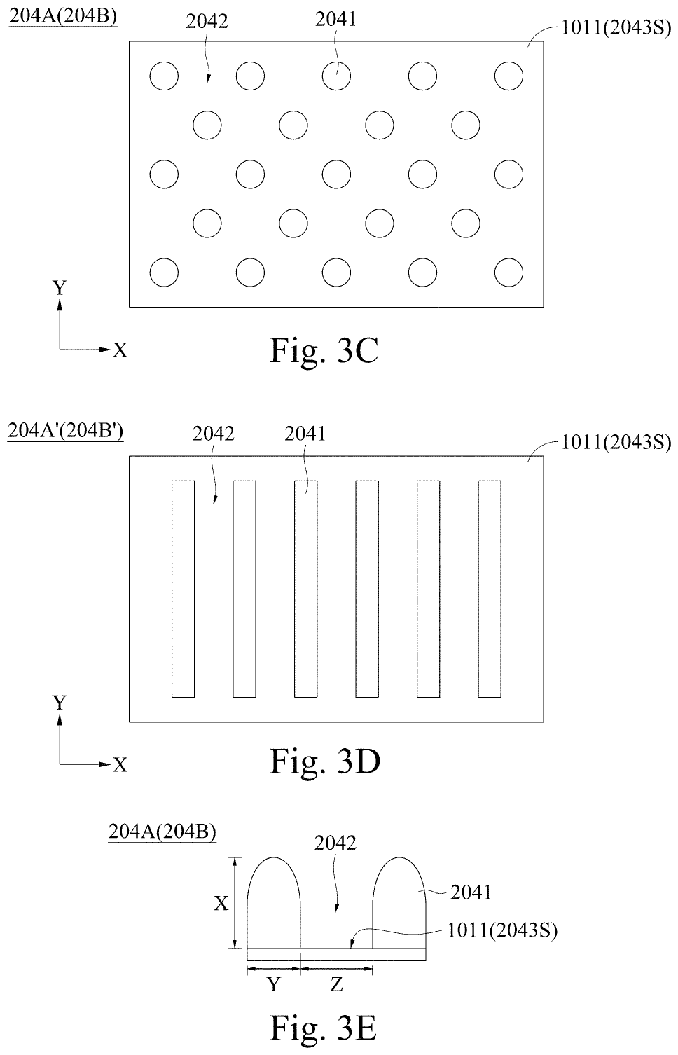

The optical structure 204 can have different structural configurations, for example, FIG. 3A and FIG. 3B show the optical structures 204A, 204B in accordance with different embodiments of the instant disclosure. As shown in FIG. 3A, the optical structure 204A includes a plurality of convex portions 2041, and the convex portions 2041 are discretely disposed on the light receiving surface 1011, and concave portions 2042 are located between two adjacent convex portions 2041. In one embodiment, the convex portion 2041 can be a cylindrical body with a dome, and the bottom of the concave portion 2042 is a flat surface, which is a portion of the light receiving surface 1011. In other embodiments, in a top view, the contour of the convex portion 2041 can be a rectangle, a square, a triangle, a hexagon, a polygon, a circle, an ellipse, or a combination thereof. In a side view, the contour of the convex portion 2041 can be a portion of a rectangle, a portion of a square, a portion of a trapezoid, a portion of a triangle, a portion of a semicircle, a portion of a circle, or a combination thereof.

As shown in FIG. 3B, the optical structure 204B includes a light-transmittable base 2043 and a plurality of convex portions 2041. The light-transmittable base 2043 has a surface 2043S, and the convex portions 2041 are located on the surface 2043S of the light-transmittable base 2043.

In one embodiment, the manufacturing process of the optical structure 204B includes a step of forming a plurality of convex portions 2041 on the light-transmittable base 2043 which is provided in advance. In another embodiment, the manufacturing process of the optical structure 204B includes a step of forming a plurality of convex portions 2041 on a surface firstly (for example, on the light receiving surface 1011 or on a surface of a temporary carrier plate), and then a light-transmittable material is filled into the concave portions 2042 with a certain height to connect the bottom portions of the convex portion 2041 and to form the light-transmittable base 2043. In the case that the optical structure 204B is formed on the temporary carrier plate, the optical structure 204B may be manufactured in advance and then is attached to the light receiving surface 1011 of the light receiver 101.

FIG. 3C is a top view of the optical structures 204A, 204B in accordance with an embodiment. In one embodiment, as shown in FIG. 3C, the convex portions 2041 are formed in a staggered arrangement on the light receiving surface 1011 or the surface 2043S. FIG. 3D is a top view of an optical structure 204A′ and an optical structure 204B′ in accordance with another embodiment. The convex portions 2041 of the optical structure 204A′ and the optical structure 204B′ are formed in a bar-shape.

FIG. 3E is a cross-sectional view of optical structures 204A, 204B in accordance with an embodiment of the instant disclosure. The convex portion 2041 of the optical structures 204A, 204B has a height X and a width Y, and the concave portion 2042 of the optical structures 204A, 204B has a width Z. As shown in FIG. 2A and FIG. 2B, in one embodiment, the incident angle θ=tan⁻¹(Z/X). For example, when θ=45°, tan⁻¹(Z/X)=45°.

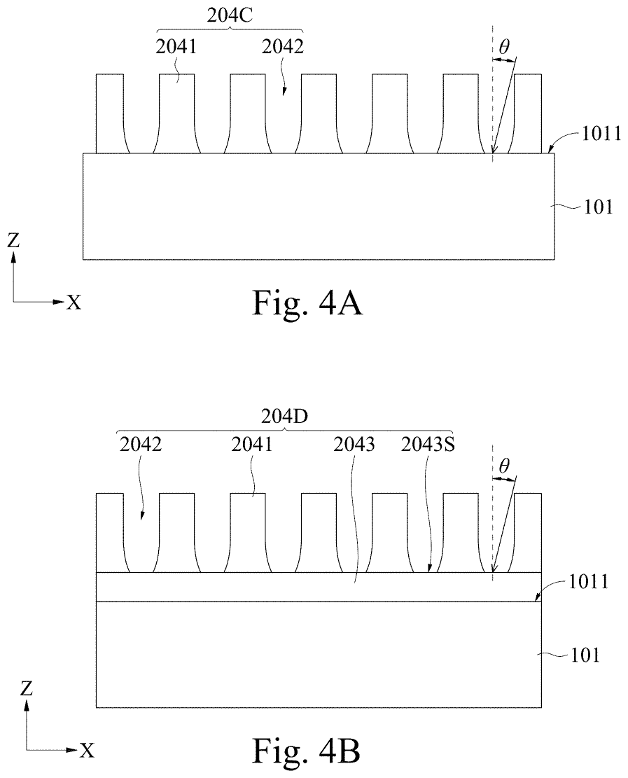

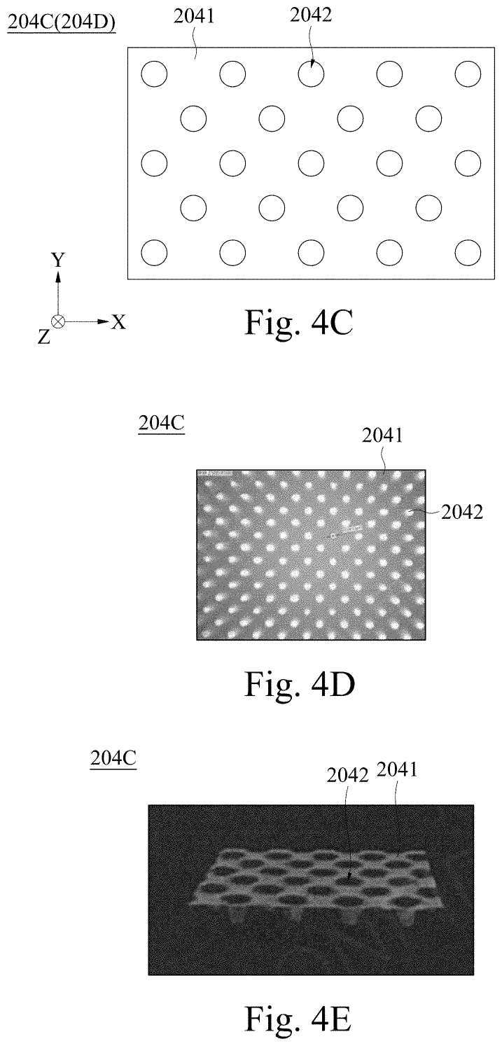

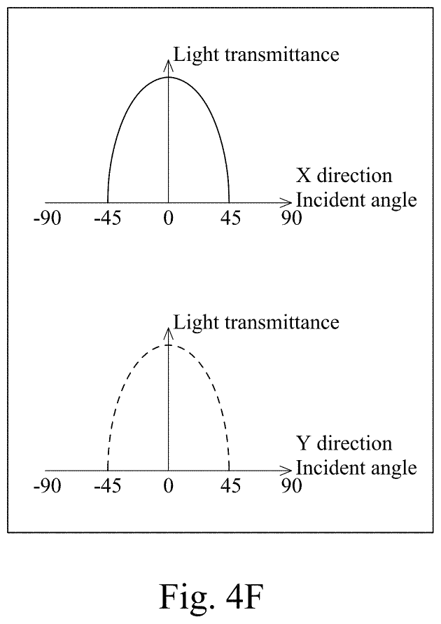

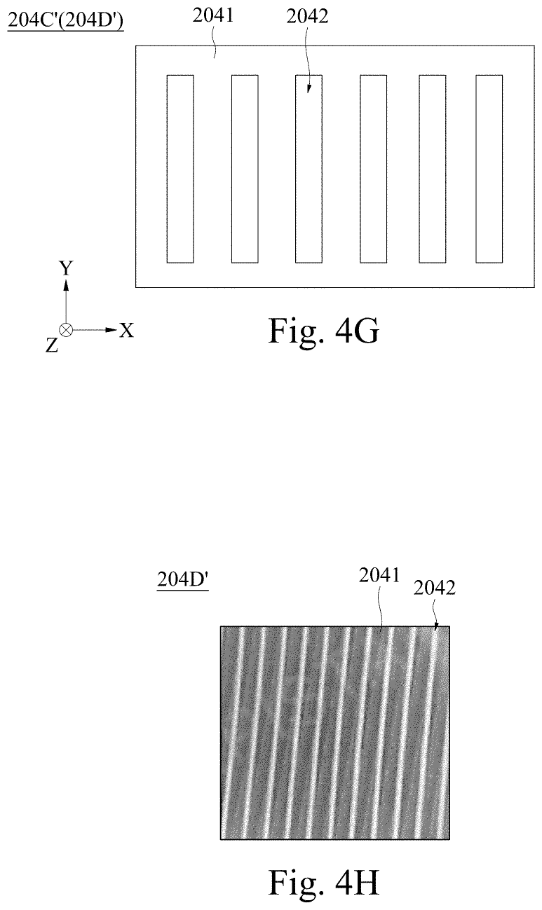

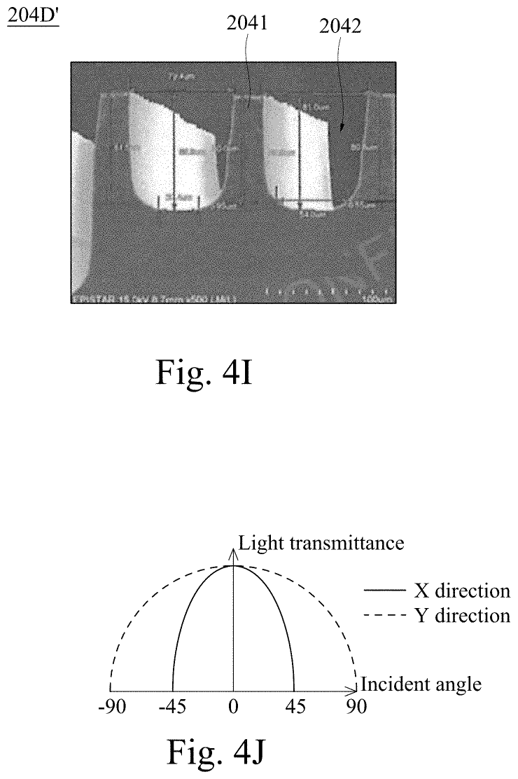

FIGS. 4A to 4E are cross-sectional views and top views of an optical structure 204C and an optical structure 204D in accordance with other embodiments. FIG. 4A is a cross-sectional view of the optical structure 204C, FIG. 4B is a cross-sectional view of the optical structure 204D, FIG. 4C is a top view of the optical structures 204C and 204D. FIG. 4D shows a photograph of the optical structure 204C in a top view, and FIG. 4E shows a photograph of the optical structure 204C in a perspective view.

As shown in FIG. 4A, the optical structure 204C includes a plurality of convex portions 2041 formed in one single sheet and on the light receiving surface 1011 of the light receiver 101. The optical structure 204C includes a plurality of concave portions 2042 exposing portions of the light receiving surface 2011. The top portion of the convex portion 2041 has a flat surface, the contour of the concave portion 2042 is a cylinder with a round corner. As shown in FIG. 4C, the contour of the concave portion 2042 is a circle. In other embodiments, in a top view, the contour of the concave portion 2042 can be a portion of a rectangle, a portion of a square, a portion of a trapezoid, a portion of a triangle, a portion of a semicircle, a portion of a circle, or a combination thereof. As shown in FIG. 4C, the concave portions 2042 are arranged in a staggered array. As shown in FIG. 4D, the light can directly pass through the concave portions 2042.

As shown in FIG. 4B, the optical structure 204D further includes a light-transmittable base 2043 with a surface 2043S, a plurality of convex portions 2041 formed on the surface 2043S of the light-transmittable base 2043, and a plurality of concave portions 2042 in the convex portions 2041 for exposing the surface 2043S of the light-transmittable base 2043. As shown in FIG. 4C, the concave portions 2042 are arranged in a staggered array. The optical structure 204D can be manufactured in advance, and then the optical structure 204D is attached to the light receiver 101. In another embodiment, the optical structure 204D can be manufactured on the light receiver 101.

FIG. 4F is a diagram showing the relationship between the incident angle θ of the light moving toward the optical structure 204C shown in FIG. 4A and the optical structure 204D shown in FIG. 4C, and the light transmittance. The horizontal axis in FIG. 4F is referred to the incident angle θ of the light, and the longitudinal axis in FIG. 4F is referred to the light transmittance of the light. FIG. 4F shows diagrams which depict that incident lights enter into the optical structures 204C, 204D on the XZ plane and the YZ plane shown in FIG. 4C. Referring to FIG. 4C, the concave portion 2042 is formed in a circle, the diagram along the X direction is therefore identical to the diagram along the Y direction. In other words, the optical structures 204C, 204D have the same light transmittances as long as the incident lights have the same incident angles θ, even though the incident lights are coming from different directions. When a light enters in a direction perpendicular to the optical structure 204C and the optical structure 204D (that is, in a direction perpendicular to the paper direction of FIG. 4C), the incident angle θ is equal to zero degree, and the light has a highest transmittance. When the incident angle θ of the light increases, the light transmittance decreases. Moreover, in the embodiment, when the incident angle θ of the light is equal to or larger than 45 degrees, the light transmittance is zero. Therefore, the optical structures 204C, 204D can suppress the ambient stray lights having greater incident angles.

FIG. 4G is a top view of an optical structure 204C′ and an optical structure 204D′ in accordance with another embodiment of the instant disclosure. The concave portions 2042 of the optical structure 204C′, 204D′ are formed in a bar-shape a with a specific spacing. FIG. 4H shows a photograph in a top view of the optical structure 204D′, and FIG. 4I shows a photograph in a perspective view of the optical structure 204D′. FIG. 4J is a diagram showing the relationship between the incident angle θ of the optical structure 204C′ and the optical structure 204D′, and the light transmittance. The horizontal axis in FIG. 4J is referred to the incident angle θ of the light, and the longitudinal axis in FIG. 4J is referred to the light transmittance of the light. The solid line in FIG. 4J indicates that the incident light enters the optical structures 204C′, 204D′ on the XZ plane shown in FIG. 4G. The dotted line in FIG. 4J indicates the incident light enters the optical structures 204C′, 204D′ on the YZ plane shown in FIG. 4G. As shown in FIG. 4G, the concave portions 2042 of the optical structures 204C′, 204D′ are formed in an elongated bar-shape (the longer side of the concave portion 2042 is parallel to the Y axis, and the shorter side of the concave portion 2042 is parallel to the X axis). Therefore, the transmittance of the light on the X axis direction is different from the transmittance of the light on the Y axis direction. When a light enters the optical structure 204C′ and the optical structure 204D′ from a direction perpendicular thereto (that is, from a direction perpendicular to the paper direction of FIG. 4G), the incident angle θ is equal to zero degree, and the light has a highest transmittance. When the incident angle θ of the light increases, the light transmittance decreases. In one embodiment, on the XZ plane, when the incident angle θ of the light is equal to or larger than 45 degrees and equal to or smaller than −45 degrees, the light transmittance is equal to zero; on the YZ plane, when the incident angle θ of the light is equal to 90 or −90 degrees, the light transmittance is equal to zero. Therefore, with changing the size of the concave portion 2042, the optical structures 204C′, 204D′ can suppress the ambient stray lights coming from different directions.

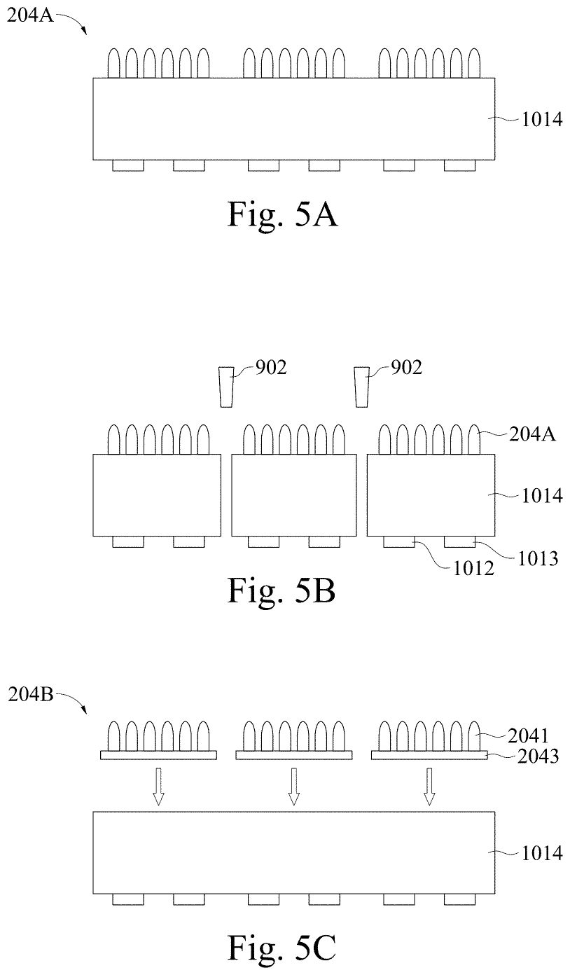

FIGS. 5A to 5C are schematic views showing a manufacturing processes of a light receiver 101 in accordance with an embodiment of the instant disclosure. It is understood that, in the following embodiments, the optical structure 204A, 204B is formed on the flip-chip type light receiver 101; however, the same manufacturing process can be adopted for the manufacturing of a vertical type light receiver 101.

FIG. 5A is a manufacturing process of the optical structure 204A in accordance with an embodiment of the instant disclosure. As shown in FIG. 5A, the upper surface of the semiconductor stack 1014 of the light receiver 101 has a patterned optical structure 204A. The method of forming the optical structure 204A includes three-dimensional printing, photolithography, electroplating, screen printing, deposition, molding, ink printing, or nanoimprint lithography. As shown in FIG. 5B, after the optical structure 204A is formed, a chip cutter 902 is utilized to divide the semiconductor stack 1014 into light receivers 101 which are separated and covered with the optical structure 204A.

FIG. 5C is a manufacturing process of the optical structure 204B in accordance with an embodiment of the instant disclosure. In one embodiment, the patterned optical structure 204B is formed in advance, and the patterned optical structure 204B is then attached to the upper surface of the semiconductor stack 1014 of the light receiver 101. For example, referring to FIG. 3B, firstly the light-transmittable base 2043 is provided, and then a plurality of convex portions 2041 is formed on the surface of the light-transmittable base 2043. Then, the optical structure 204 formed with the convex portions 2041 is disposed on the upper surface of the semiconductor stack 1014. In one embodiment, the optical structure 204 is attached to the upper surface of the semiconductor stack 1014 by an optical glue to form the optical structure 204B. Next, referring to FIG. 5B, the chip cutter 902 is utilized to divide the semiconductor stack 1014 into light receivers 101 which are separated and covered with the optical structure 204B.

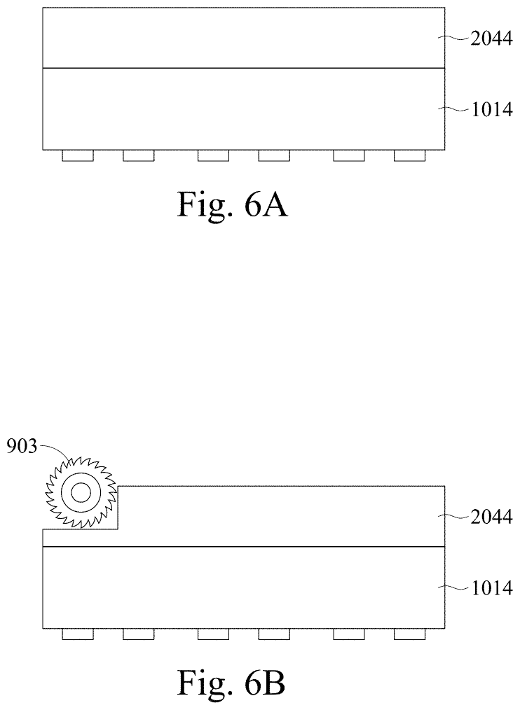

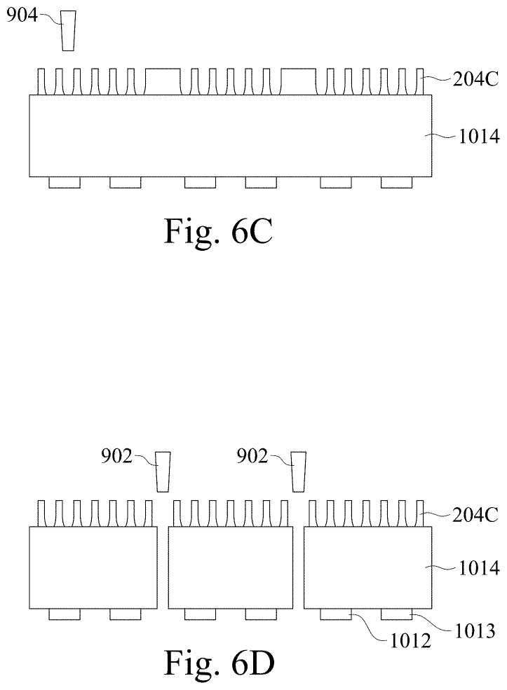

FIGS. 6A to 6D are schematic views showing a manufacturing processes of a light receiver 101 in accordance with another embodiment of the instant disclosure. It is understood that, in the following embodiments, the optical structure 204C is formed on the flip-chip type light receiver 101. The identical manufacturing process can be applied to a vertical type light receiver 101. As shown in FIG. 6A, the optical material layer 2044 is coated on the upper surface of the semiconductor stack 1014. The material of the optical material layer 2044 can refer to the aforementioned material of the optical structure 204.

FIG. 6B is a manufacturing process of adjusting the height of the optical material layer 2044. The optical material layer 2044 is rolled and compacted to a preset height (for example, the height X of the convex portion 2041 shown in FIG. 3E) by a roller 903. In one embodiment, the optical material layer 2044 can be made of an optical material with higher malleability, and the material of the optical material layer 2044 can be resin. In other embodiment, the optical material layer 2044 is polished to the preset height by polishing process.

FIG. 6C is a manufacturing process of processing the optical material layer 2044 into the optical structure 204C. A cutter 904 (for example, a blade or a laser) is utilized to divide the optical material layer 2044 into a plurality of concave portion 2042 on the optical material layer 2044 and from the optical structure 204C. In other embodiment, the manufacturing processes shown in FIG. 6B and FIG. 6C can be combined together. For example, the combined manufacturing process can adopt a roller 903 having a blade or a tooth structure; the roller 903 rolls and compacts the optical material layer 2044 to the preset height, and during the rolling step, a plurality of concave portions 2042 is extruded on the optical material layer 2044. As shown in FIG. 6D, after the optical structure 204C is formed, the chip cutter 902 is utilized to divide the semiconductor stack 1014 into light receivers 101 which are separated and covered with the optical structure 204C.

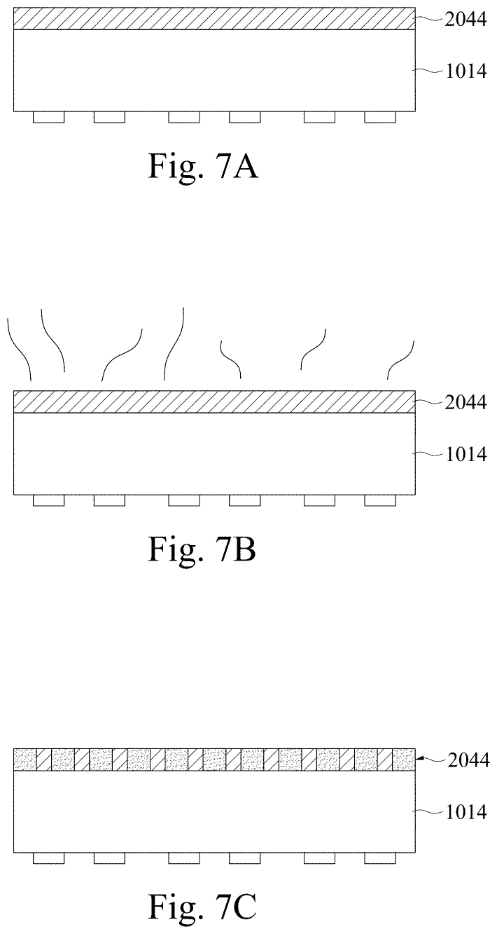

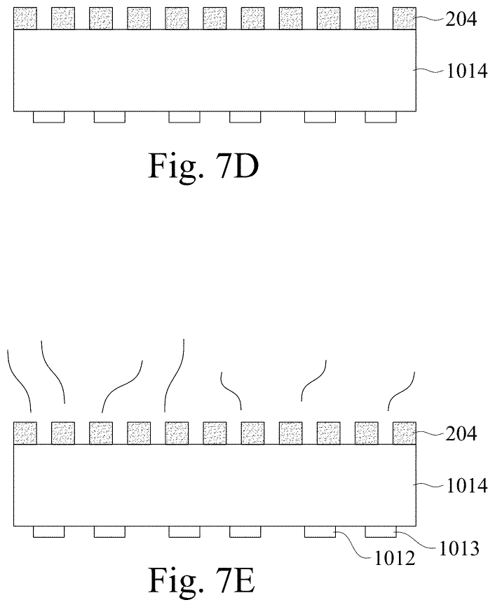

FIGS. 7A to 7E are schematic views showing a manufacturing processes of a light receiver 101 in accordance with another embodiment of the instant disclosure. It is understood that, in the following embodiments, the optical structure 204 is formed on the flip-chip type light receiver 101. The same manufacturing process can be applied to a vertical type light receiver 101. As shown in FIG. 7A, the optical material layer 2044 is coated on the upper surface of the semiconductor stack 1014. In one embodiment, the coating of the optical material layer 2044 can adopt a spin-coating process to uniformly distribute the optical material layer 2044 over the upper surface of the semiconductor stack 1014. The coating height of the optical material layer 2044 is greater than or equal to the height of the optical structure 204 (for example, the height X of the convex portion 2041 shown in FIG. 3E). In one embodiment, the material of the optical material layer 2044 is an opaque photoresist material, for example a black or magenta-colored photoresist material. The photoresist material can be a positive photoresist or a negative photoresist, which depends on that the optical structure 204 is the concave portions 2042 or the convex portions 2041.

FIG. 7B is a soft bake process of the optical material layer 2044. The soft bake process can increase the adhesion between the optical material layer 2044 and the semiconductor stack 1014, and remove the solvents contained in the optical material layer 2044. In one embodiment, the optical material layer 2044 is selected from the SU8 photoresist, the soft bake temperature can be in a range between 90 Celsius degrees and 110 Celsius degrees, and the soft bake time is ranged between 50 and 70 minutes.

FIG. 7C is an exposure process of the optical material layer 2044. In the process, the light passes through the mask (not shown) with a preset pattern and illuminates the surface of the optical material layer 2044, so that the degree of resin cross-linking of the illuminated portions of the optical material layer 2044 is changed. The holes of the mask are corresponding to the concave portions 2042 or the convex portions 2041 of the optical structure 204. In one embodiment, with the positive photoresist, the holes of the mask are corresponding to the concave portions 2042 of the optical structure 204. With the negative photoresist, the holes of the mask are corresponding to the convex portions 2041 of the optical structure 204.

FIG. 7D is a manufacturing process of processing the optical material layer 2044 into the optical structure 204. After the optical material layer 2044 is exposed, portions of the optical material layer 2044 corresponding to the concave portions 2042 are removed to complete the fixing process. For example, the optical material layer 2044 are removed by using isopropanol or other organic solvents, and then the optical material layer 2044 is washed out in deionized water. With the negative photoresist, before the fixing process, the optical material layer 2044 is baked to increase the material bonding strength, and then the washing of the photoresist of the optical material layer 2044 is performed.

FIG. 7E is a hard bake process of the optical material layer 2044. In one embodiment, the hard bake temperature of the semiconductor stack 1014 is greater than the glass transition temperature of the optical material layer 2044. The hard bake process strengthens the entire structure of the optical material layer 2044. In one embodiment, the optical material layer 2044 is selected from the SU8 photoresist, the hard bake temperature is ranged between 120 Celsius degrees and 200 Celsius degrees, and the hard bake time is ranged between 20 and 40 minutes. After the optical structure 204 is formed, referring to FIG. 6D, the chip cutter 902 is provided to divide the semiconductor stack 1014 into light receivers 101 which are separated and covered with the optical structure 204.

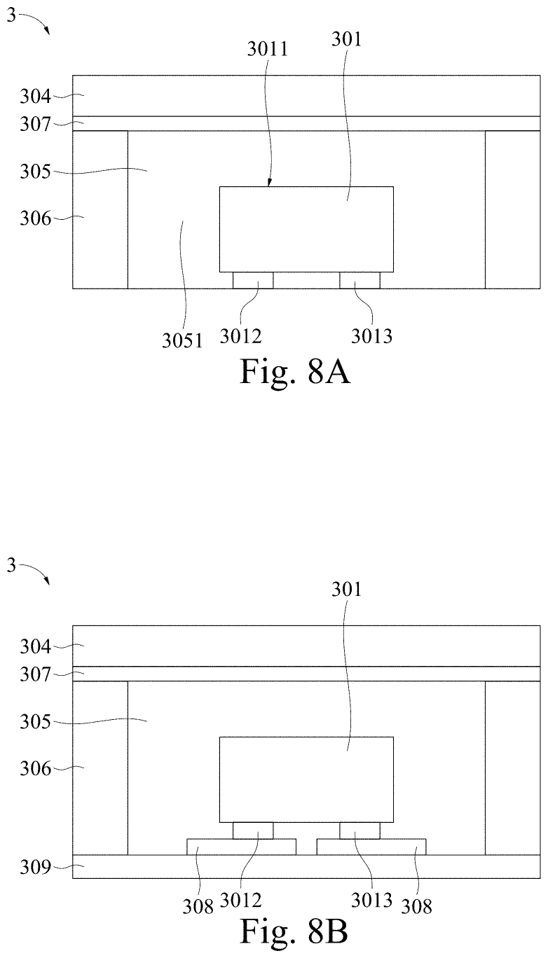

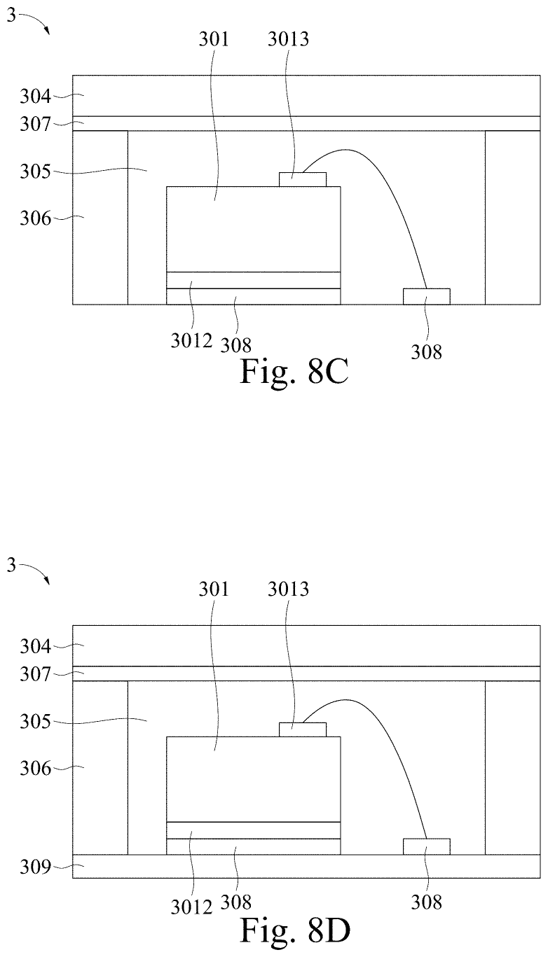

Referring to FIG. 8A, the optical sensing device 3 includes a housing 306, a light receiver 301, a transparent layer 307, and an optical structure 304. The housing 306 and the transparent layer 307 define a cavity 305, the light receiver 301 is disposed in the cavity 305 and surrounded by the housing 306, and the side surface of the light receiver 101 does not directly contact the housing 306. In one embodiment, the transparent layer 307 is disposed on the top portion of the housing, and the optical structure 304 is disposed on the upper surface of the transparent layer 307. In other embodiments, the transparent layer 307 and the optical structure 304 are formed in advance, and then the transparent layer 307 and the optical structure 304 are together formed on the top portion of the housing 306. The transparent layer 307 provides a better adhesion between the optical structure 304 and the housing 306, so that the structure of the optical structure 304 becomes more rigid. In one embodiment, the cavity 305 is filled with a light-transmittable material 3051, an upper surface of the light-transmittable material 3051 and the top portion of the housing 306 are substantially coplanar, and the transparent layer 307 is formed on the upper surface of the light-transmittable material 3051. In other embodiments, the cavity 305 is not filled with the light-transmittable material 3051 (for example, the cavity 305 is vacuumed). Adoption of a rigid transparent layer 307 is beneficial to maintain a flat surface on the optical structure 304. In another embodiment, the transparent layer 307 is omitted, and the optical structure 304 is directly formed on the upper surface of the light-transmittable material 3051.

The material of the transparent layer 307 can be silicone, epoxy resin, polyimide (PI), benzocyclobutene (BCB), perfluorocyclobutane (PFCB), Su8 photoresist, acrylic resin, poly(methyl methacrylate) (PMMA), polyethylene terephthalate (PET), polycarbonate (PC), polyetherimide (PEI), fluorocarbon polymer, aluminum oxide (Al₂O₃), siloxane polymer (SINR), or spin-on glass (SOG).

As shown in FIG. 8A, the optical sensing device 3 adopts a flip-chip type light receiver 301. The first electrode pad 3012 and the second electrode pad 3013 are disposed on a bottom portion of the light receiver 301 and serve as contacts of electrical connection between the optical sensing device 3 and the circuit board. As shown in FIG. 8B, the optical sensing device 3 also adopts a flip-chip type light receiver 301. In one embodiment, the first electrode pad 3012 and the second electrode pad 3013 are directly connected to (e.g., using solders or silver pasts) contact pads 308 on the substrate 309. As shown in FIG. 8C, the optical sensing device 3 adopts a vertical type light receiver 301. In one embodiment, the first electrode pad 3012 is disposed on the bottom portion of the light receiver 301 and the second electrode pad 3013 is disposed on the top portion of the light receiver 301. Two contact pads 308 are formed on the bottom portion of the package structure of the optical sensing device 3, one of the contact pads 308 and the first electrode pad 3012 are partially or completely overlapped with each other in a vertical direction and are electrically connected to each other, and the other contact pad 308 is electrically connected to the second electrode pad 3013 via wire bonding. As shown in FIG. 8D, the optical sensing device 3 also adopts a vertical type light receiver 301. In one embodiment, the first electrode pad 3012 and one of the two contact pads 308 on the substrate 309 are partially or completely overlapped with each other in a vertical direction and are electrically connected to each other, and the second electrode pad 3013 is connected to the other contact pad 308 on the substrate 309 via wire bonding.

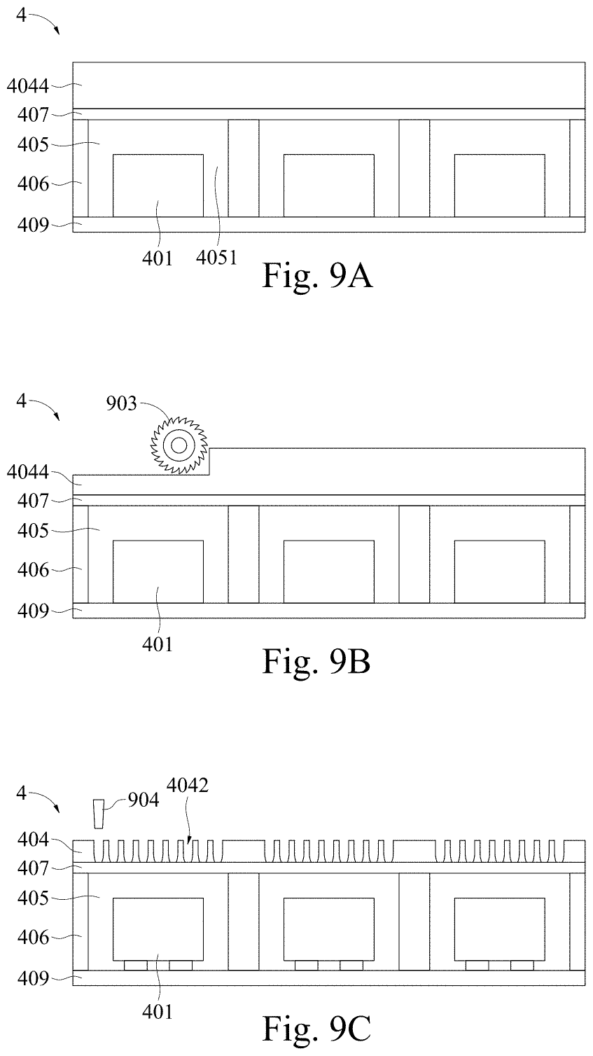

Referring to FIG. 9A, the optical sensing device 4 includes a substrate 409, a housing 406, a transparent layer 407, and an optical material layer 4044. The housing 406 is disposed on the upper surface of the substrate 409, and the housing 406 and the substrate 409 define a plurality of separated cavities 405. A light receiver 401 is disposed in one of the cavities 405 and surrounded by the housing 406, and the side surfaces of the light receiver 401 do not contact the housing 406. In other embodiments, the light receivers 401 shown in FIG. 9A can be replaced by light emitters 102 or other electronic elements. The transparent layer 407 is disposed on the top portion of the housing 406. In one embodiment, the optical material layer 4044 can be directly coated on the upper surface of the transparent layer 407, and the optical material layer 4044 can form the optical structure 404 after the optical material layer 4044 is processed. In other embodiments, the cavities 405 are filled with the light-transmittable material 4051, the transparent layer 407 can be omitted, and the optical material layer 4044 is directly coated on the top surface of the light-transmittable material 4051 and/or the top surface of the housing 406.

As shown in FIG. 9A, in one embodiment, the optical material layer 2044 is coated on the whole top surface of the transparent layer 407 or merely coated on a portion of the top surface of the transparent layer 407 right above the cavities 405.

As shown in FIG. 9B, the optical material layer 4044 is rolled and compacted to a preset height (for example, the height X of the convex portion 2041 shown in FIG. 3E) by a roller 903. In one embodiment, the optical material layer 4044 can be made of an optical material with a higher malleability, and the material of the optical material layer 2044 can be resin. In other embodiments, the optical material layer 4044 is polished to the preset height by polishing.

As shown in FIG. 9C, a cutter 904 (for example, a blade or a laser) is utilized to divide the optical material layer 4044 to form a plurality of concave portion 4042 on the optical material layer 4044 and form the optical structure 404. In other embodiments, the manufacturing processes shown in FIG. 9B and FIG. 9C can be combined together. For example, the combined manufacturing process can adopt a roller 903 having a blade or a tooth structure; the roller 903 rolls and compacts the optical material layer 4044 to the preset height, and during the rolling process, a plurality of concave portions 4042 is extruded on the optical material layer 4044. It is understood that, the manufacturing process of this embodiment is applied to the optical sensing device 4 having a plurality of cavities 405, the manufacturing process of this embodiment can also be applied to the optical sensing devices 4 in accordance with the embodiments shown in FIG. 8A and FIG. 8B. For example, the optical sensing device 4 having a plurality of cavities 405 can be further divided, so that a plurality of optical sensing devices 4 having a single cavity 405 can be formed.

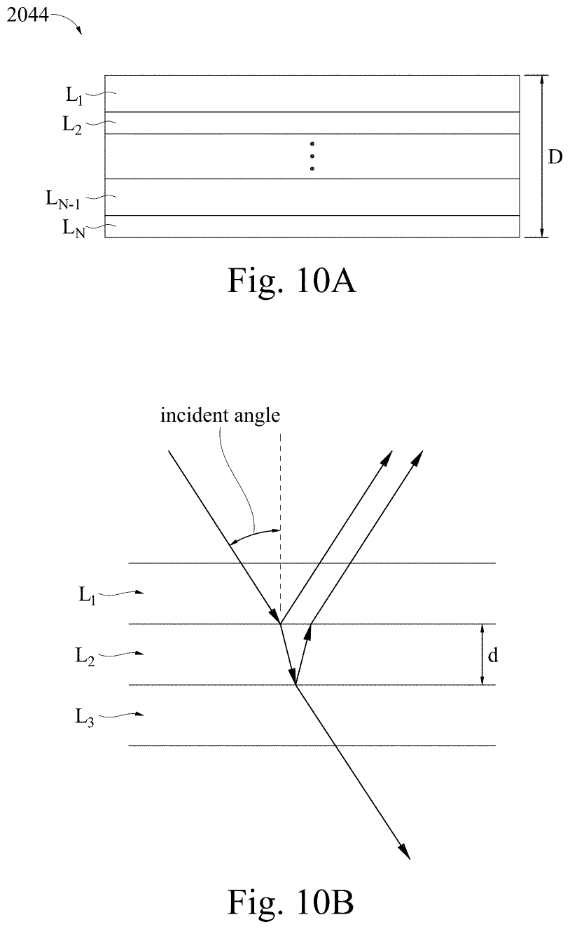

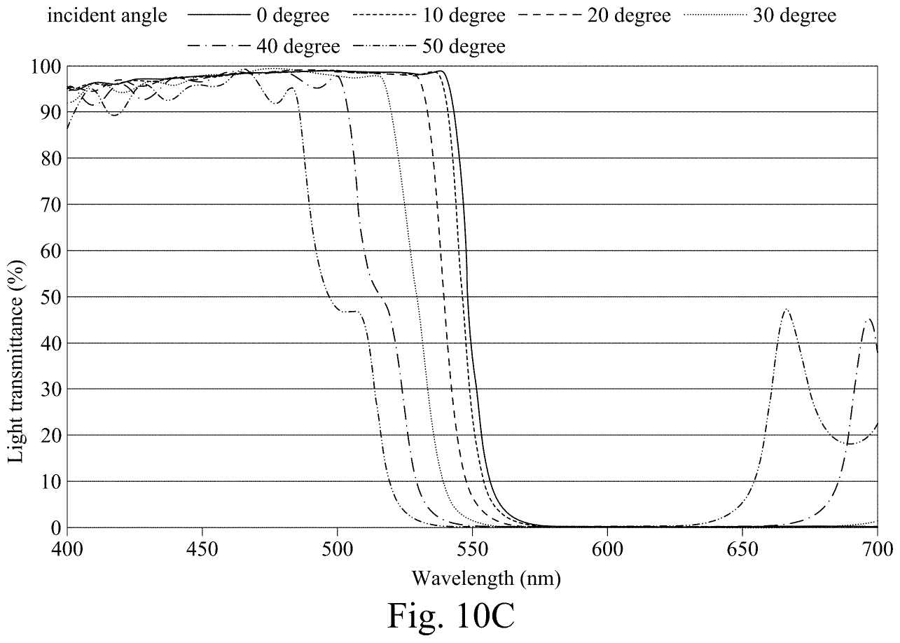

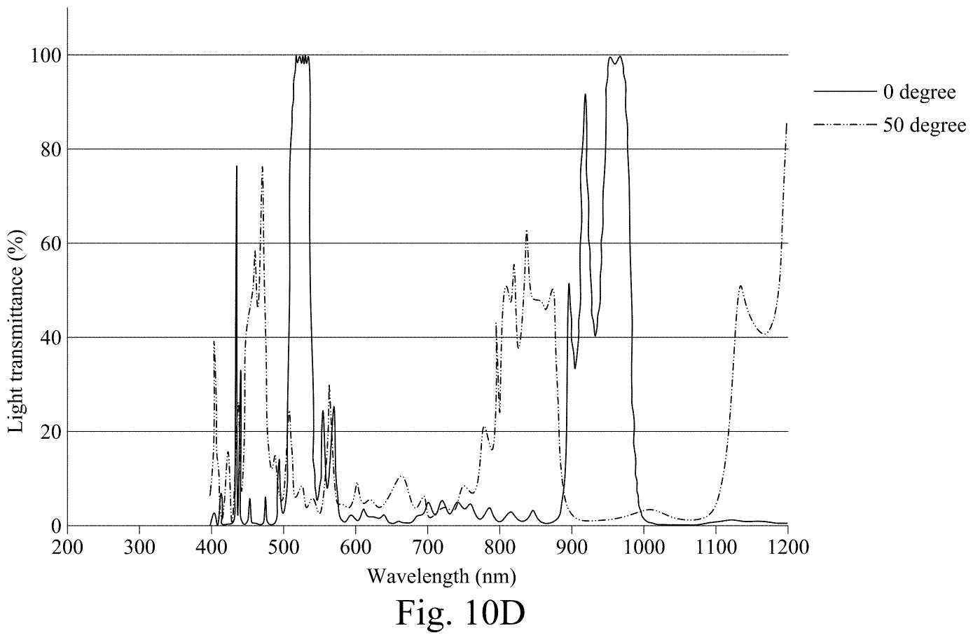

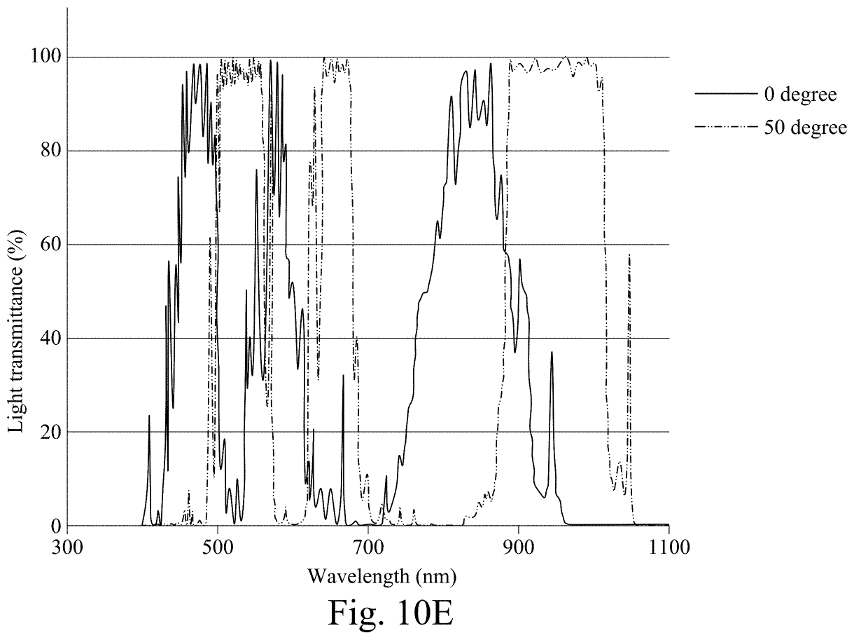

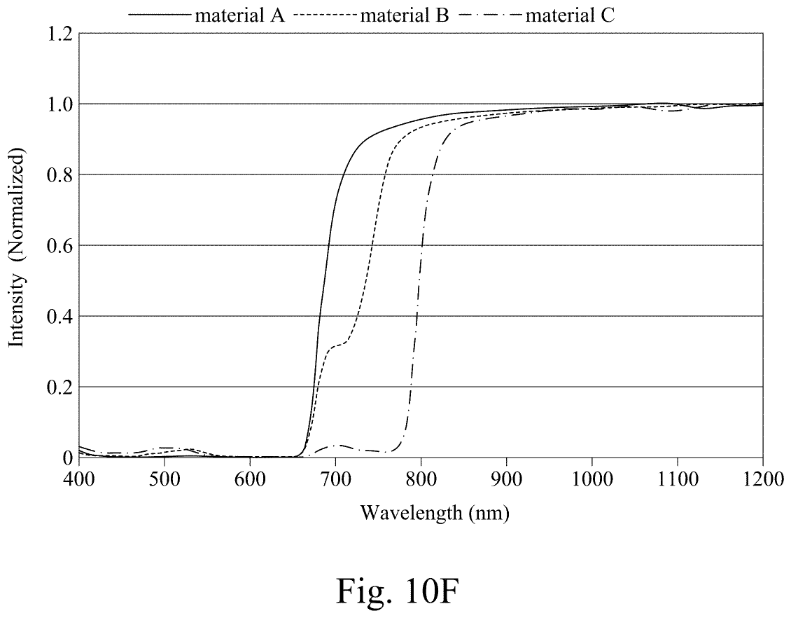

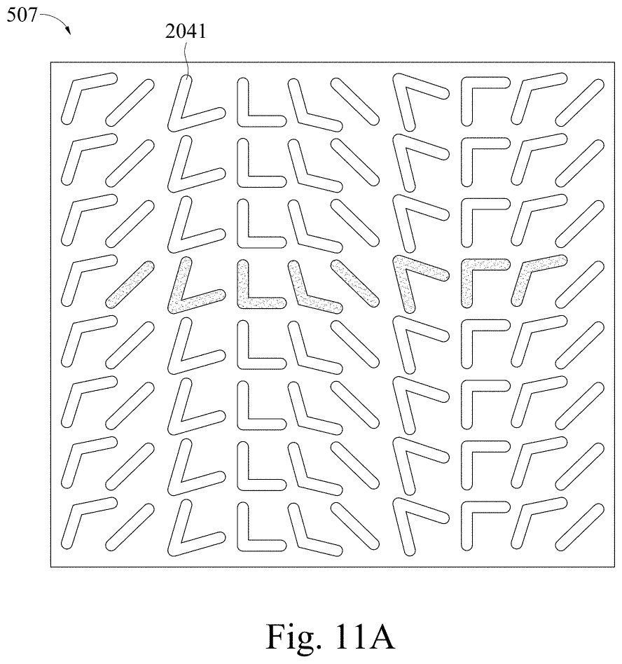

Referring to FIG. 10A, the optical material layer 2044 is a multilayered structure. The optical material layer 2044 has a thickness D and has layers L1-LN. The thickness D and the number of the layers L1-LN can be modified in accordance with the specification of the light receiver 101, wherein the number of the layers L1˜LN and the thickness of each of the layers L1˜LN can be designed according to the thickness D and the preset maximum incident angle θ of the light receiver 101.

As shown in FIG. 10B, the layers L1, L2, L3 are arranged in repeated pairs of high/low refraction indexes, so that lights within specific wavelength ranges have destructive interferences to reduce the light transmittance. The phase thickness d of the layer L2 can be calculated according to Equation 1:

d=(2π/λ)×N_{d} (Equation 1).

Wherein, λ is the wavelength of the light, and N_{d} is the optical depth of the layer L2.

FIG. 10C is a diagram showing the relationship between the wavelength of the light passing through the optical structure 204 and the light transmittance. Referring to FIG. 10C, the horizontal axis in FIG. 10C is referred to the wavelength (nm) of the light, and the longitudinal axis in FIG. 10C is referred to the light transmittance of the optical structure 204. In one embodiment, the optical structure 204 is a multilayered structure having titanium oxide and silicon oxide alternately stacked with each other. The optical structure 204 has twenty sublayers, the total thickness of the optical structure 204 is 2 μm, and the film thickness of each of the sublayers is shown in Table 1 below. As shown in FIG. 10C, the optical structure 204 has a higher transmittance in a light wavelength range less than 570 nm, and the larger the incident angle θ is, the narrower the light wavelength range corresponding to the transmittance greater than 90% is. In other words, the larger the incident angle θ is, the smaller the maximum light wavelength corresponding to the transmittance greater than 90% is. Therefore, ambient stray light with a larger incident angle θ and a longer wavelength is more difficult to penetrate the optical structure layer 204 as shown in FIG. 10C.

FIG. 10D is a diagram showing the relationship between the wavelength of the light passing through the optical structure 204 and the light transmittance. The horizontal axis in FIG. 10D is referred to the wavelength (nm) of the light, and the longitudinal axis in FIG. 10D is referred to the light transmittance of the optical structure 204. As shown in FIG. 10D, the optical structure 204 has higher transmittances to incident lights in two specific wavelength ranges, and the shorter the wavelength of the incident light is, the larger the incident angle is. For example, in one embodiment, the optical structure 204 is a multilayered structure having tantalum oxide (Ta₂O₅) and magnesium fluoride (MgF₂) alternately stacked with each other. The optical structure 204 has sixty-one sublayers, the total thickness of the optical structure 204 is 7.25 μm, and the film thickness of each of the sublayers is shown in Table 2 below. As shown in FIG. 10D, when the incident angle θ of the light is greater than 50 degrees, the light transmittances of the green light (the wavelength is between 500 nm and 600 nm) and the infrared light (the wavelength is between 900 nm and 1100 nm) are lower. However, when the incident angle θ of the light is zero degree, the light transmittances of the green light and the infrared light are greater than 90%. Therefore, ambient stray lights having a greater incident angle θ (especially the green lights and the infrared lights) can hardly pass through the optical structure 204 as shown in FIG. 10D.

FIG. 10E is a diagram showing the relationship between the wavelength of the light passing through the optical structure 204 and the light transmittance. The horizontal axis in FIG. 10E is referred to the wavelength (nm) of the light, and the longitudinal axis in FIG. 10E is referred to the light transmittance of the optical structure 204. As shown in FIG. 10E, the optical structure 204 has a higher transmittance to incident lights in three specific wavelength ranges, and the shorter the wavelength of the incident light is, the larger the incident angle is. In one embodiment, the optical structure 204 is a multilayered structure having tantalum oxide (Ta₂O₅) and magnesium fluoride (MgF₂) alternately stacked with each other, the optical structure 204 has one hundred and six sublayers, and the total thickness of the optical structure 204 is 19 μm. As shown in FIG. 10E, when the incident angle θ of the light is greater than 50 degrees, the light transmittances of the green light (the wavelength is between 500 nm and 550 nm), the red light (the wavelength is between 600 nm and 700 nm), and the infrared light (the wavelength is between 900 nm and 1100 nm) are lower. However, when the incident angle θ of the light is zero degree, the light transmittances of the green light, the red light, and the infrared light are greater than 90%. Therefore, ambient stray lights having a greater incident angle θ (especially the green lights, the red lights, and the infrared lights) can hardly pass through the optical structure 204 as shown in FIG. 10E.

FIG. 10F is a diagram showing the relationship between the intensity of the near infrared light passing through different materials and the wavelength. The horizontal axis in FIG. 10F is referred to the wavelength (nm) of the light, and the longitudinal axis in FIG. 10F is referred to the normalized intensity of the light. In one embodiment, the material A, the material B, and the material C are materials through which a near infrared (NIR) light can pass. The material A is permissible to the red light with a wavelength greater than 650 nm and the infrared light, the material B is permissible to the deep red light with a wavelength greater than 700 nm and the infrared light, and the material C is permissible to the infrared light with a wavelength greater than 800 nm. Therefore, in different application scenarios, optical structures with different materials can be adopted to remove ambient stray lights in different wavelength ranges.

In another embodiment, the optical structure 204 includes a polarized film to remove the S-polarized light. For example, the optical structure 204 is a multilayered structure having titanium oxide and silicon oxide alternately stacked with each other. The optical structure has twenty-one sublayers, the total thickness of the optical structure 204 is 2.696 μm, and the film thickness of each of the sublayers is shown in Table 3 below. Because the S-polarized light often appears in the reflected lights and the reflected lights are considered as noises in photoplethysmography, the filtration of the S-polarized light can be deemed as a filtration of the noise in the light, the signal-to-noise ratio therefore can be increased.

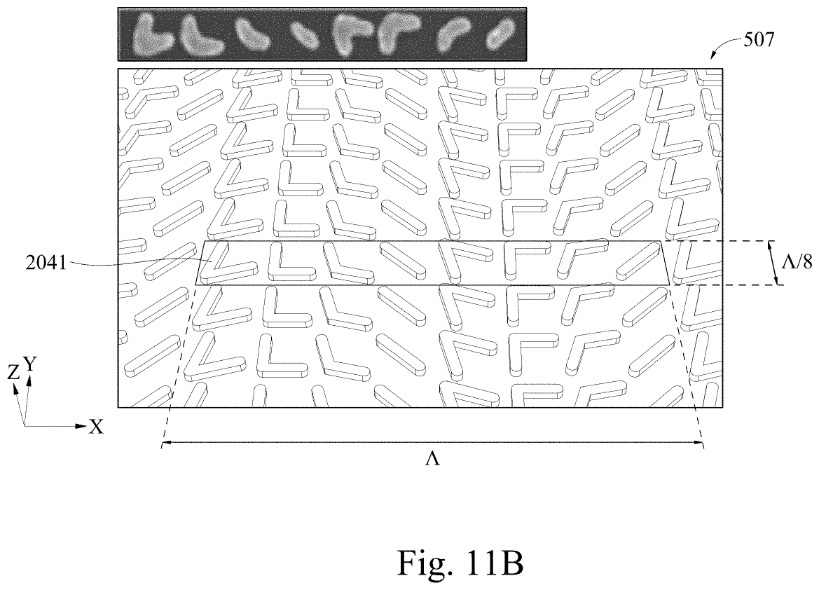

As shown in FIG. 11A, in one embodiment, the optical structure 204 has a microstructure layer 507, the microstructure layer 507 has convex portions 2041, and the convex portions 2041 are patterned structures in nanoscale. The microstructure 507 can be made of metal, organic, or oxide. The oxide can be indium tin oxide. The metal can be gold, silver, copper, platinum, or the like. The organic can be polyimide, silicone-based resin, or epoxy. Referring to FIG. 11B, in one embodiment, eight convex portions 2041 of the microstructure 507 are grouped as a pattern unit, the length (Λ) of the pattern unit in the X axis is 1440 nm, and the width (Λ/8) of the pattern unit in the Y axis is 180 nm. The microstructure layer 507 includes a plurality of pattern units repeated in the X axis and the Y axis.

Equation 2 hereunder shows the relationship between the abnormal refractive index and the phase:

$$nt sin ( θ ) - ni sin ( θ i ) = \frac{λ 0}{2 π} \frac{d ∅}{d x} . \qquad ( Equation 2 )$$

Wherein, nt and ni are the refractive indexes of media, θ is the incident angle, θi is the refractive angle, λ₀ is the wavelength of the light in the vacuum, and

$$\frac{d ∅}{d x}$$

is the phase gradient of the plane on which the patterned structure is located. According to Equation 2, if

$$\frac{d ∅}{dx}$$

is zero, then the generalized Snell's law is degenerated to a traditional Snell's law; if

$$\frac{d ∅}{dx}$$

is not zero, the condition is deviated from the traditional Snell's law, and the refractive light and reflected light which are deviated from the traditional law are named as an abnormal refracted light. With the phase of the abnormal refracted light, the focusing position of light can be derived from Equation 3:

$$∅ ( x , y ) = \frac{2 π}{λ} \sqrt{{x}^{2} + {y}^{2} + {f}^{2}} - f . \qquad ( Equation 3 )$$

Wherein, f is the focal length, λ₀ is the wavelength of abnormal refracted light, and x, y are design constants.

In one embodiment, the microstructure layer 507 causes a destructive interferences in the incident lights with greater incident angles θ. Hence, the incident lights with greater incident angles θ cannot pass through the microstructure layer 507, the ambient stray lights are therefore reduced.

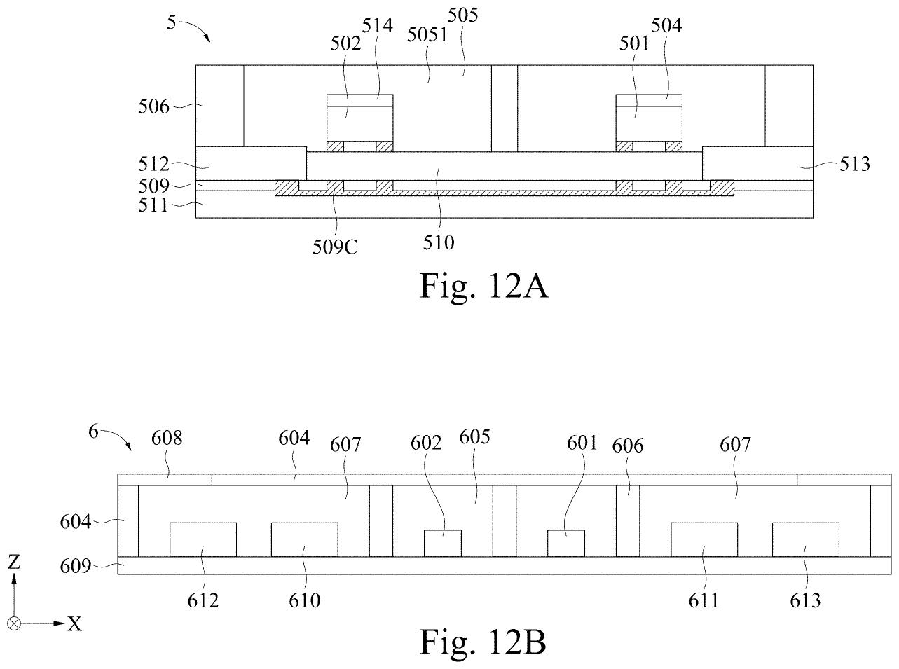

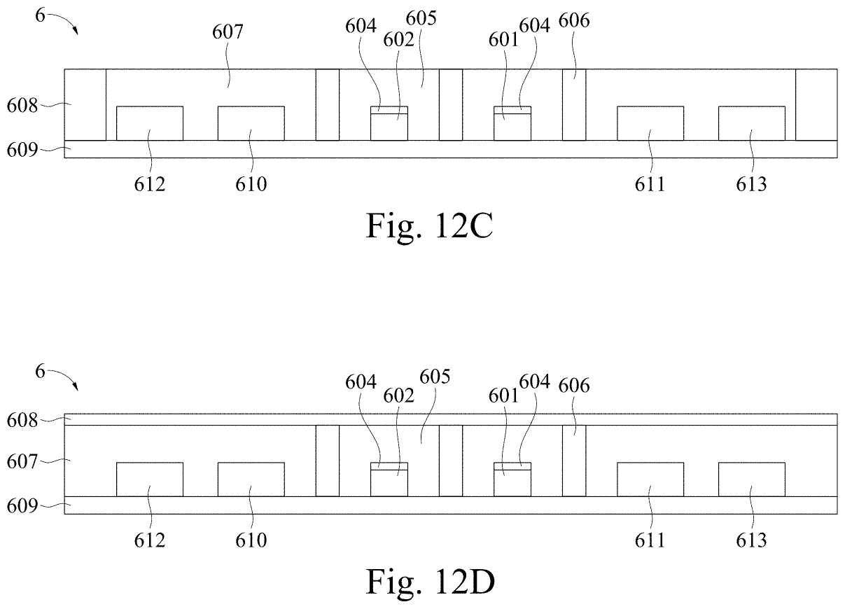

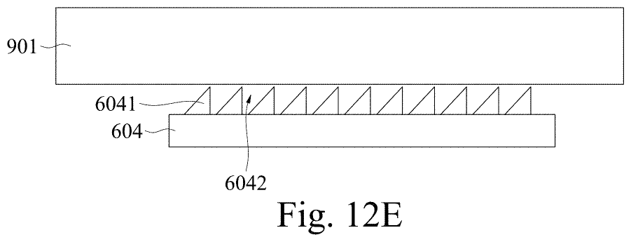

As shown in FIG. 12A, in one embodiment, the optical sensing device 5 includes a substrate 509, a housing 506, a light receiver 501, a light emitter 502, a power module 511, a processor 510, a communication module 512, and an amplifier module 513. The processor 510, the communication module 512, and the amplifier module 513 are collectively referred to as a control circuit. The processor 510, the communication module 512, and the amplifier module 513 are disposed above the substrate 509, and the power module 511 is disposed below the substrate 509, so that the overall size of the optical sensing device 5 can be reduced. The housing 506 is disposed on the upper surface of the substrate 509, and the housing 506 and the substrate 509 define two independent cavities 505. The light receiver 501 and the light emitter 502 are respectively disposed in the two separated cavities 505, and the light receiver 501 and the light emitter 502 are respectively surrounded by the housing 506. In one embodiment, the cavity 505 is filled with a light-transmittable material 5051. In other embodiments, the cavity 505 can be vacuumed, filled with air, or filled with an inert gas. In one embodiment, an optical structure 504 is disposed on the light receiver 101 to retard the ambient stray lights. Likewise, an optical structure 514 is also disposed on the light emitter 502 to collimate the light which moves to the skin tissue of the human. According to different requirements, the optical structure 504 on the light receiver 101 and the optical structure 514 on the light emitter 502 can be identical or different from each other. In one embodiment, the optical structure 504 is not disposed on the light receiver 501 and/or the light emitter 502.

The substrate 509 is electrically connected to the light emitter 502, the light receiver 501, the control circuit, and the power module 511. The power module 511 of the control circuit can be compatible with wireless charging or wired charging. For example, the power module 511 has an induction coil, and the optical sensing device 5 can be placed on a wireless charger for wireless charging. The communication module 512 of the control circuit can be compatible with wireless communication or wired communication. In one embodiment, after the signal detected by the light receiver 101 is processed by the processor 510, the processed signal can be transmitted to other electronic devices for further processing or display. The communication module 512 for wireless transmission adopts a communication protocol including but not limited to, global system for mobile communication (GSM), personal handy-phone system (PHS), code division multiple access (CDMA) system, wideband code division multiple access (WCDMA) system, long term evolution (LTE) system, worldwide interoperability for microwave access (WiMAX) system, wireless fidelity (Wi-Fi) system, or Bluetooth.

As shown in FIG. 12B, in one embodiment, the optical sensing device 6 includes a substrate 609, a housing 606, a light receiver 601, a light emitter 602, a processor 610, a power module 611, a communication module 612, and an amplifier module 613. The light receiver 601, the light emitter 602, the processor 610, the power module 611, the communication module 612, and the amplifier module 613 are all disposed above the substrate 609 to reduce the overall height of the optical sensing device 6. The housing 606 is disposed on the upper surface of the substrate 609, and the housing 606 and the substrate 609 define a plurality of separated cavities 605. The light receiver 601, the light emitter 602, the processor 610 with the communication module 612, and the power module 611 with the amplifier module 613 are disposed in four separated cavities 605 and surrounded by the housing 606, respectively. In one embodiment, the substrate 609 is a flexible substrate, and the light emitter 602, the light receiver 601, and other electronic elements are electrically connected to the flexible substrate 609. In one embodiment, the cavities 605 in which the processor 610, the power module 611, the communication module 612, and the amplifier module 613 reside can be filled with protection layer 607 to protect the components placed in the cavities 605. Moreover, the cavities 605 in which the light emitter 602 and the light receiver 601 reside can also be filled with a light-transmittable material 6051. The protection layer 607 can be made of a transparent material or an opaque material. The material of the protection layer 607 can be silicone, epoxy resin, polyimide (PI), benzocyclobutene (BCB), perfluorocyclobutane (PFCB), Su8 photoresist, acrylic resin, poly(methyl methacrylate) (PMMA), polyethylene terephthalate (PET), polycarbonate (PC), polyetherimide (PEI), fluorocarbon polymer, aluminum oxide (Al₂O₃), siloxane polymer (SINR), spin-on glass (SOG), polyurethane (PU), polydimethylsiloxane (PDMS), hydrocolloid, hot glue, or rubber.

In one embodiment, the optical structure 604 covers the cavities 605 in which the light receiver 601 and the light emitter 602 reside to eliminate the ambient stray lights with greater incident angles. In other embodiments, the optical structure 604 merely covers the cavity 605 in which the light receiver 601 resides. In one embodiment, an adhesive layer 608 is disposed above the cavity 605 which is beneficial to fix the optical sensing device 6 on the surface of the skin tissue 901. Therefore, when the optical sensing device 6 is attached to the surface of the skin tissue 901, the optical structure 604 also directly covers the surface of the skin tissue 901, thereby the ambient lights with greater incident angles are reduced. The material of the adhesive layer 608 can be selected from a biocompatible material (for example, a medical-level material is compatible with the ISO 10993 standard), and includes medical-level elastomer, silicone rubber, polyurethane, hydrocolloid, rubber, or silicone to prevent side effects such as skin allergy, erosion, or irritation.

In one embodiment, the housing 606, the light emitter 602, the light receiver 601, and other electronic elements are disposed on the same side of the substrate, thereby increasing the flexibility of the optical sensing device 6. The substrate 609 has a longer axis (X axis) and a shorter axis perpendicular to the long axis (Y axis). The light receiver 601, the light emitter 602, and other electronic elements are arranged along the longer axis, and separated from each other by a gap. For example, a gap exists between the communication module 612 and the processor 610, between the processor 610 and the housing 606, between the housing 606 and the light emitter 602, between the light emitter 602 and the housing 606, between the housing and the light receiver 601, between the light receiver 601 and the housing 606, between the housing 606 and the power module 611, and between the power module 611 and the amplifier module 613. No electronic element exists in the gap. As shown in FIG. 12B, it is acceptable to move the power module 611 to the back side of the communication module 612 (the direction perpendicular to the paper direction); however, it is not preferable to move the power module 611 to the space between the communication module 612 and the processor 610. The optical sensing device 6 are therefore separated into several sections by several gaps. Hence, when the optical sensing device 6 is bent, the element of the optical sensing device 6 does not collide with each other, thereby the overall flexibility is increased. In other embodiments, the chips of the electronic elements can be stacked with each other, and the chips are connected to the substrate 609 through wire bonding, thereby the total area occupied by the electronic elements is decreased, and the overall flexibility of the optical sensing device 6 is increased. In one embodiment, the electronic elements can adopt flexible elements to increase the overall flexibility of the optical sensin 6. As shown in FIG. 12C, the optical structure 604 can be disposed on the surface of the light receiver 601 and/or the surface of the light emitter 602, and the adhesive layer 608 is disposed on a side portion of the optical sensing device 6. Therefore, portions of the optical sensing device 6 can be bent and adhered with each other (for example, wrapping around the user's arm) to prevent the adhesive layer 60 from directly adhering to the human body. Hence, the wearing comfort can be improved.

As shown in FIG. 12D, the optical structure 604 can be disposed on the surface of the light receiver 601 and/or the surface of the light emitter 602, and the adhesive layer 608 is disposed above the protection layer 607 and continuously covers the electronic elements, the cavities 605, and the housing 606 below the protection layer 607.

In one embodiment, the material of the adhesive layer 608 adopts the light-transmittable material which is at least permittable to light with the target wavelength. In other embodiment, the adhesive layer 608 is merely disposed on the upper surface of the optical sensing device 6 but does not cover the cavity 605 in which the light receiver 601 resides, so that the light is not blocked by the adhesive layer 608. The material of the adhesive layer 608 can be a light-transmittable material or an opaque material.

As shown in FIG. 12E, in one embodiment, the optical structure 604 of the optical sensing device 6 shown in FIG. 12B is adapted to contact human body, the optical structure 604 has a comb-shaped structure, and the comb-shaped structure has a plurality of convex portions 6041. When the optical structure 604 of the optical sensing device 6 contacts skin having hairs, the comb-shaped convex portion 6041 can push away the hairs, so that the light receiver 601 can approach much closer to the skin, the measurement interference caused by the hairs can be reduced.

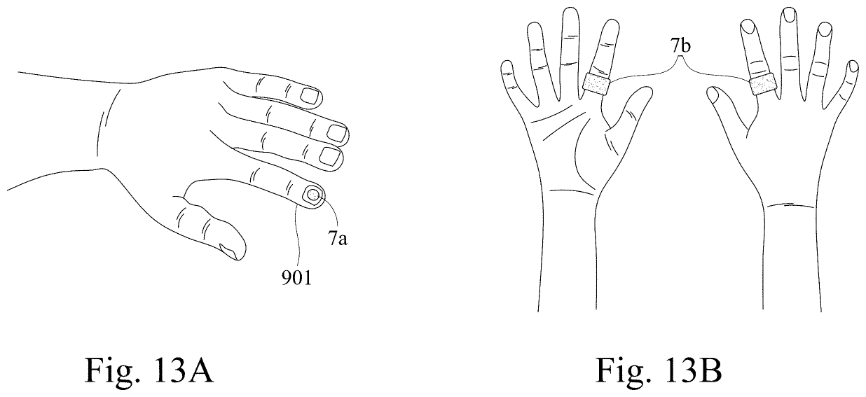

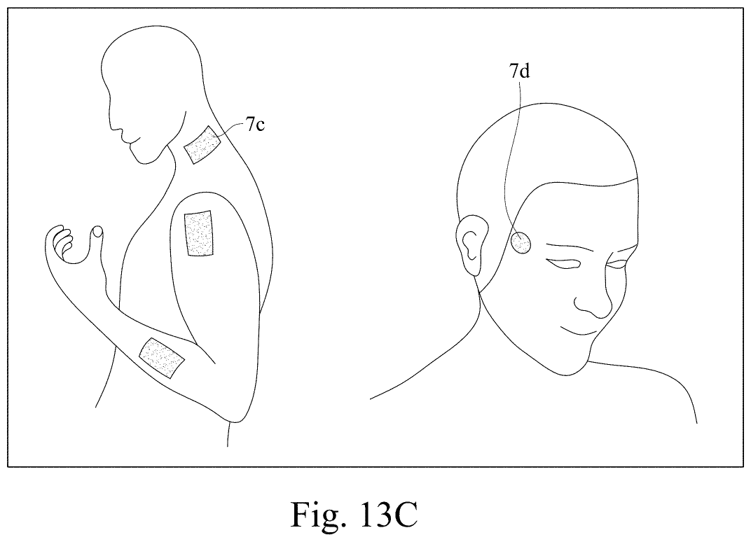

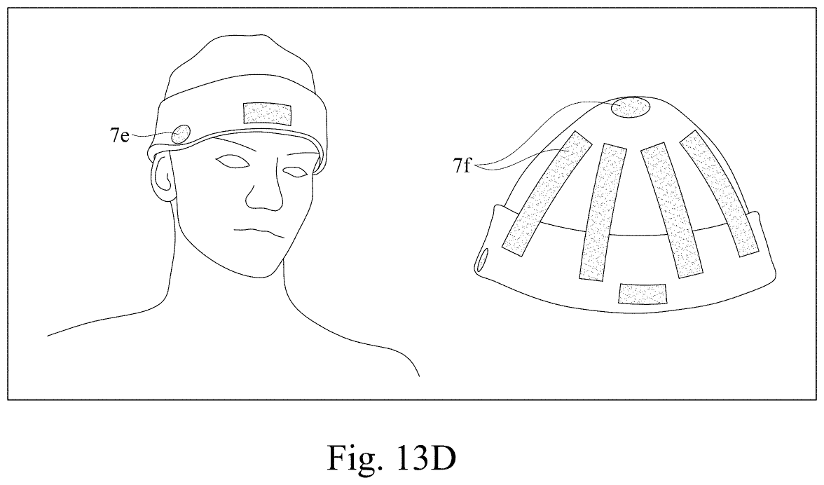

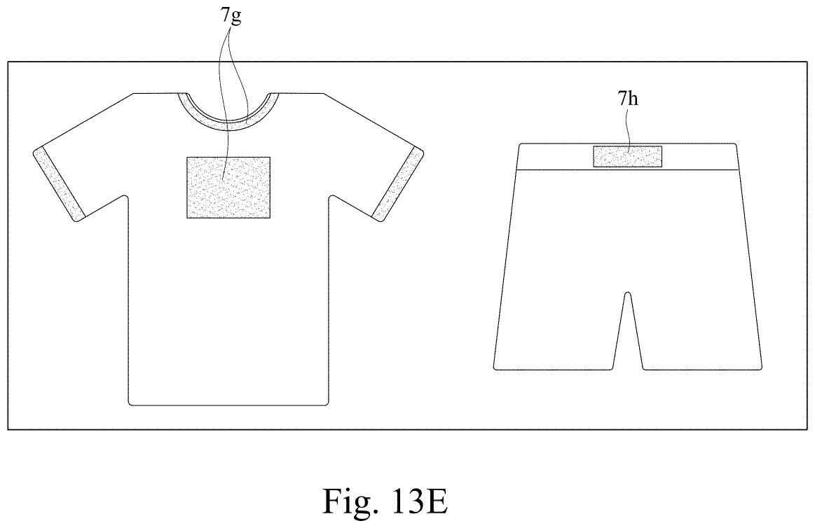

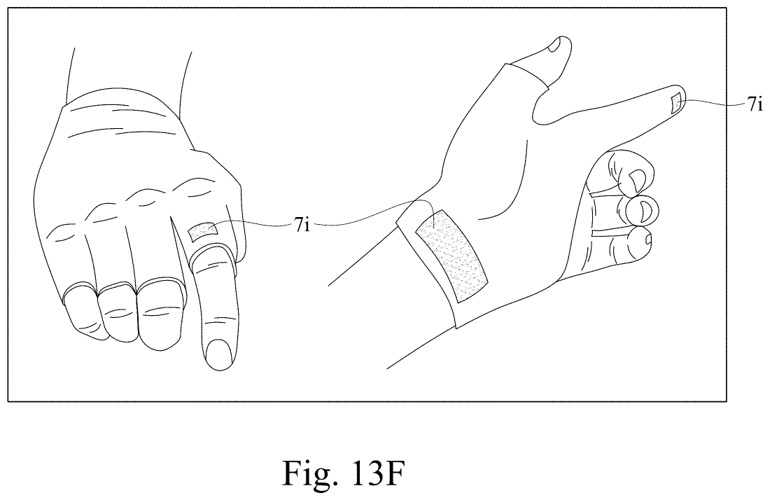

FIGS. 13A to 13F are schematic views showing the application scenarios of optical sensing devices in accordance with different embodiments of the instant disclosure. The optical sensing device 7a shown in FIG. 13A is applied to a nail patch to measure the signals coming from the skin tissue 901 under the nail. The nail does not have nerves and can be easily affixed to the optical sensing device 7a. Therefore, the optical sensing device 7a can provide the user with the advantages of higher optical stability. Moreover, upon using the optical sensing device 7a, the user has less abnormal sensation. Furthermore, the user can carry the optical sensing device 7a conveniently. Moreover, it is understood that, even if for the user who has darker skin, the skin color under the nail is still not very dark. Therefore, performing the signal measurement at the nail position has the advantage of being less affected by racial differences. The optical sensing device shown in FIG. 13B is applied to a ring 7b to measure the signals coming from the skin of the finger portion. The optical sensing devices 7c, 7d shown in FIG. 13C are applied to reusable or disposable patches so as to be attached to different portions of the body for performing the measurement. The optical sensing devices 7e, 7f shown in FIG. 13D are sewed on the inner surfaces of hats. The optical sensing devices 7g, 7h shown in FIG. 13E are sewed on the inner surfaces of clothes. The optical sensing device 7i shown in FIG. 13F is sewed on the inner surface of a glove. As the optical sensing devices 7e, 7f, 7g, 7h, 7i contact the skin tissues 901 of the wearer, the optical sensing devices 7e, 7f, 7g, 7h, 7i can measure signals coming from the several positions of the skin tissue 901. With integrating with different accessories, the optical sensing device can continuously monitor on or perform biometric authentication through various physiological parameters of users such as cardiovascular disease patients (respiratory rate, heartrate variation), diabetic patients (blood sugar, dehydration), respiratory arrest patients (oxygen concentration), and exercise users (respiratory rate, heartrate variation, dehydration, blood oxygen concentration, calories).

Based on the above, in accordance with one embodiment of the instant disclosure, the optical sensing device filters the noise lights by using the optical structure to increase the accuracy of the optical sensing device. In accordance with one embodiment, the optical structure adopts a multilayered structure to filter noise lights in different wavelength ranges to increase the accuracy of the optical sensing device. In accordance with one embodiment, the optical sensing device can adopt a flexible structure, so that the optical sensing device can be applied to cloths, accessories, or other wearable objects. Moreover, the flexible structure can provide the optical sensing device a more comfortable fit with the skin tissue, thereby the distance between the light receiver and the skin tissue can be reduced, and thus the accuracy of the optical sensing device is increased.

TABLE 1
the sublayers of the optical structure
of the embodiment shown in FIG. 10C.

| Sublayer | Material | Film thickness (nm) |
|---|---|---|
| 1 | TiO₂ | 89.42 |
| 2 | SiO₂ | 104.5 |
| 3 | TiO₂ | 83.98 |
| 4 | SiO₂ | 80.06 |
| 5 | TiO₂ | 85.11 |
| 6 | SiO₂ | 85.66 |
| 7 | TiO₂ | 79.96 |
| 8 | SiO₂ | 113.03 |
| 9 | TiO₂ | 63.88 |
| 10 | SiO₂ | 119.35 |
| 11 | TiO₂ | 64.08 |
| 12 | SiO₂ | 105 |
| 13 | TiO₂ | 76.88 |
| 14 | SiO₂ | 95.79 |
| 15 | TiO₂ | 67.68 |
| 16 | SiO₂ | 126.02 |
| 17 | TiO₂ | 56.15 |
| 18 | SiO₂ | 144.28 |
| 19 | TiO₂ | 55.06 |
| 20 | SiO₂ | 54.74 |

TABLE 2
the sublayers of the optical structure
of the embodiment shown in FIG. 10D.

| Sublayer | Material | Film thickness (nm) |
|---|---|---|
| 1 | Ta₂O₅ | 170.54 |
| 2 | MgF₂ | 88.11 |
| 3 | Ta₂O₅ | 38.13 |
| 4 | MgF₂ | 57.83 |
| 5 | Ta₂O₅ | 59.54 |
| 6 | MgF₂ | 87.92 |
| 7 | Ta₂O₅ | 45.64 |
| 8 | MgF₂ | 78.23 |
| 9 | Ta₂O₅ | 48.19 |
| 10 | MgF₂ | 51.4 |
| 11 | Ta₂O₅ | 226.28 |
| 12 | MgF₂ | 46.56 |
| 13 | Ta₂O₅ | 53.47 |
| 14 | MgF₂ | 94.89 |
| 15 | Ta₂O₅ | 33.76 |
| 16 | MgF₂ | 99.18 |
| 17 | Ta₂O₅ | 41.99 |
| 18 | MgF₂ | 51.83 |
| 19 | Ta₂O₅ | 28.72 |
| 20 | Ta₂O₅ | 150.83 |
| 21 | MgF₂ | 214.09 |
| 22 | Ta₂O₅ | 124.82 |
| 23 | MgF₂ | 206.35 |
| 24 | Ta₂O₅ | 98.61 |
| 25 | MgF₂ | 236.23 |
| 26 | Ta₂O₅ | 126.72 |
| 27 | MgF₂ | 226.83 |
| 28 | Ta₂O₅ | 140.22 |
| 29 | MgF₂ | 200.35 |
| 30 | Ta₂O₅ | 129.69 |
| 31 | MgF₂ | 185.02 |
| 32 | Ta₂O₅ | 131.45 |
| 33 | MgF₂ | 199.04 |
| 34 | Ta₂O₅ | 147.78 |
| 35 | MgF₂ | 250.44 |
| 36 | Ta₂O₅ | 120.44 |
| 37 | Ta₂O₅ | 1.91 |
| 38 | MgF₂ | 285.18 |
| 39 | Ta₂O₅ | 59.42 |
| 40 | MgF₂ | 124.47 |
| 41 | Ta₂O₅ | 61.12 |
| 42 | MgF₂ | 328.93 |
| 43 | Ta₂O₅ | 66.39 |
| 44 | MgF₂ | 122.26 |
| 45 | Ta₂O₅ | 71.81 |
| 46 | MgF₂ | 130.83 |
| 47 | Ta₂O₅ | 48.26 |
| 48 | MgF₂ | 95.86 |
| 49 | Ta₂O₅ | 222.41 |
| 50 | MgF₂ | 126.24 |
| 51 | Ta₂O₅ | 92.13 |
| 52 | MgF₂ | 149.01 |
| 53 | Ta₂O₅ | 90.97 |
| 54 | MgF₂ | 122.78 |
| 55 | Ta₂O₅ | 82.25 |
| 56 | MgF₂ | 138.99 |
| 57 | Ta₂O₅ | 96.58 |
| 58 | MgF₂ | 134.71 |
| 59 | Ta₂O₅ | 87.73 |
| 60 | MgF₂ | 134.31 |
| 61 | Ta₂O₅ | 84.48 |

TABLE 3
the sublayers of the optical structure adopting the polarized film.

| Sublayer | Material | Film thickness (nm) |
|---|---|---|
| 1 | SiO₂ | 216.04 |
| 2 | TiO₂ | 91.27 |
| 3 | SiO₂ | 158.85 |
| 4 | TiO₂ | 80.52 |
| 5 | SiO₂ | 172.26 |
| 6 | TiO₂ | 76.63 |
| 7 | SiO₂ | 195.09 |
| 8 | TiO₂ | 73.93 |
| 9 | SiO₂ | 190.64 |
| 10 | TiO₂ | 68.49 |
| 11 | SiO₂ | 169.58 |
| 12 | TiO₂ | 71.08 |
| 13 | SiO₂ | 179.36 |
| 14 | TiO₂ | 48.28 |
| 15 | SiO₂ | 189.37 |
| 16 | TiO₂ | 71.06 |
| 17 | SiO₂ | 132.03 |
| 18 | TiO₂ | 83.4 |
| 19 | SiO₂ | 166.06 |
| 20 | TiO₂ | 47.08 |
| 21 | SiO₂ | 215.06 |

What is claimed is:

1. An optical sensing device, comprising:
a substrate;
a housing disposed on an upper surface of the substrate, wherein the housing and the substrate define a first cavity;
a light receiver disposed in the first cavity, wherein the housing surrounds the light receiver; and
an optical structure disposed on an upper surface of the light receiver, wherein the optical structure comprises a plurality of concave portions and a plurality of convex portions, the concave portions and the convex portions are alternately arranged to form an array, and a light transmittance of the concave portions is greater than a light transmittance of the convex portions.

2. The optical sensing device according to claim 1, wherein a maximum width of the concave portions is equal to a maximum height of the convex portions.

3. The optical sensing device according to claim 1, wherein the concave portions of the optical structure are a plurality of holes, and the array is arranged as a checkerboard configuration.

4. The optical sensing device according to claim 1, wherein the concave portions of the optical structure are a plurality of grooves, and the array is arranged as a one-dimensional bar array.

5. The optical sensing device according to claim 1, wherein the optical structure comprises a plurality of first material layers and a plurality of second material layers stacked with each other alternately, and a reflection index of the first material layers is greater than a reflection index of the second material layers.

6. The optical sensing device according to claim 1, wherein the housing and the substrate further define a second cavity, the optical sensing device further comprises a light emitter disposed in the second cavity, and the housing surrounds the light emitter.

7. The optical sensing device according to claim 6, wherein the optical structure is further disposed on an upper surface of the light emitter.

8. The optical sensing device according to claim 6, wherein the substrate is a flexible substrate having a long axis and a short axis perpendicular to the long axis, the optical sensing device further comprises a plurality of electronic elements, the light receiver, the light emitter, and the electronic elements are disposed along the long axis and spaced from each other by a gap.

9. An optical sensing device, comprising:
a substrate;
a housing disposed on an upper surface of the substrate, wherein the housing and the substrate define a first cavity;
a light receiver disposed in the first cavity, wherein the housing surrounds the light receiver;
a light-transmittable material filled in the first cavity, wherein an upper surface of the light-transmittable material and an upper surface of the housing are coplanar; and
an optical structure disposed on an upper surface of the light-transmittable material, wherein the optical structure comprises a plurality of concave portions and a plurality of convex portions, the concave portions and the convex portions are alternately arranged to form an array, and a light transmittance of the concave portions is greater than a light transmittance of the convex portions.

10. The optical sensing device according to claim 9, wherein the housing and the substrate further define a second cavity, the optical sensing device further comprises a light emitter disposed in the second cavity, and the housing surrounds the light emitter; the light-transmittable material is further filled in the second cavity, the upper surface of the light-transmittable material in the first cavity and the second cavity are coplanar with the upper surface of the housing, and the optical structure is disposed on the upper surface of the light-transmittable material in the first cavity and the second cavity.
